(19) United States
(12) Patent Application Publication
(10) Pub. No.: US 2024/0074287 A1
(43) Pub. Date: Feb. 29, 2024

(54) DISPLAY APPARATUS

(71) Applicant: LG Display Co., Ltd., Seoul (KR)

(72) Inventors: Hyesun SON, Seoul (KR); Sejin JANG, Paju-si (KR); JunHa HWANG, Siheung-si (KR); Minwan KIM, Paju-si (KR)

(73) Assignee: LG Display Co., Ltd., Seoul (KR)

(21) Appl. No.: 18/211,021

(22) Filed: Jun. 16, 2023

(30) Foreign Application Priority Data
Aug. 31, 2022 (KR) 10-2022-0110295

(51) Int. Cl. H10K 59/80; C09J 157/10; C09J 163/00

(52) U.S. Cl. CPC H10K 59/87; C09J 157/10; C09J 163/00

(57) ABSTRACT

Discussed is a display apparatus including a transistor part over a substrate, a light emitting part over the transistor part, one or more cover members over the light emitting part, and one or more first adhesives disposed between the one or more cover members. The transmittance of the one or more first adhesives can be less than about 97%.

### CROSS-REFERENCE TO RELATED APPLICATIONS

This application claims priority to Korean Patent Application No. 10-2022-0110295 filed on Aug. 31, 2022, in the Republic of Korea, the entire contents of which are hereby expressly incorporated by reference into the present application.

### BACKGROUND OF THE DISCLOSURE

### Field

The present disclosure relates to a display apparatus.

### Discussion of the Related Art

As our society enters the full-fledged information era, various display apparatuses which process and display large amounts of information have been developed and commercialized. In various types of display apparatuses to display images, there are a liquid crystal display apparatus, an organic light emitting display apparatus, and an electro-phoretic display apparatus, for example.

There is a trend among users that those who watch broadcasts or videos or enjoy video games through the display apparatus prefer portable display apparatus having a large screen. However, when the screen of the portable display apparatus is larger, a portability of the display apparatus can be reduced, so there can be a limit to configure a large screen of the display apparatus. In order to meet both the large screen and the portability needs, research on a foldable display apparatus that can fold and unfold a display panel is also actively conducted.

### SUMMARY OF THE DISCLOSURE

Various studies for reducing components of a display apparatus are conducted in order to reduce the thickness of the display apparatus so that a display panel can be folded and unfolded. When the components of the display apparatus are reduced, there may be a limitation in performance of the display apparatus due to the reduction of the components that affects the reflectance of the display apparatus.

Accordingly, the inventors of the present disclosure recognized the problems or limitations mentioned above and conducted various experiments to improve the reflectance of the display apparatus, and to improve the performance of the display apparatus. Through various experiments, a new display apparatus was invented, in which the reflectance of the display apparatus and the performance of the display apparatus can be enhanced.

An aspect of the present disclosure is to provide a display apparatus in which the reliability of the display apparatus can be enhanced by improving the reflectance.

Accordingly, embodiments of the present disclosure are directed to an apparatus that substantially obviates one or more of the problems due to limitations and disadvantages of the related art.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

A display apparatus according to an example embodiment of the present disclosure includes one or more plates including a display area and a hole area, a transistor part over the one or more plates, a light emitting part over the transistor part and one or more cover members over the light emitting part. The display apparatus includes one or more first adhesives disposed between the one or more cover members and in the display area. The display apparatus includes one or more second adhesives disposed at the hole area and the one or more second adhesives can be different from the one or more first adhesives.

A display apparatus according to an example embodiment of the present disclosure includes a transistor part over a substrate, a light emitting part over the transistor part, and one or more cover members over the light emitting part. The display apparatus includes one or more first adhesives disposed between the one or more cover members, and a transmittances of one or more first adhesives can be 80% or less.

According to an example embodiment of the present disclosure, since the reflectance of the display apparatus can be improved by lowering the transmittance of the adhesive applied to the display apparatus, the performance and/or reliability of the display apparatus can be improved.

According to an example embodiment of the present disclosure, since the adhesive applied to the display apparatus includes an ultraviolet blocker, a display apparatus having an improved color coordinate and/or luminance can be provided.

According to an example embodiment of the present disclosure, since the adhesive applied to the display apparatus includes dye, according to a ratio of a dye, a display apparatus having a desired reflective visibility by providing various reflective visibilities can be provided.

According to an example embodiment of the present disclosure, since the adhesive applied to the display apparatus is partially surface-treated, a display apparatus can be provided in which a curvature in a variable area can be reduced.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing general description and the following detailed description of the present disclosure are example and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 illustrates a display apparatus according to an example embodiment of the present disclosure.

FIG. 2 is a cross-sectional view taken along a line I-I′ of FIG. 1.

FIGS. 3A to 3C are perspective views illustrating a display apparatus according to an example embodiment of the present disclosure.

FIG. 4A illustrates a display apparatus according to an example embodiment of the present disclosure.

FIG. 4B illustrates a display apparatus according to another example embodiment of the present disclosure.

FIG. 5 illustrates transmittances of adhesives according to Experimental Examples and Example Embodiments of the present disclosure.

FIG. 6 illustrates the adhesive according to an example embodiment of the present disclosure.

FIG. 7 illustrates a color coordinate according to an example embodiment of the present disclosure.

FIG. 8 illustrates a luminance reduction rate according to an example embodiment of the present disclosure.

FIG. 9A illustrates reflective visibility according to Comparative Examples and Example Embodiments of the present disclosure.

FIG. 9B illustrates a color coordinate for explaining reflective visibility according to an example embodiment of the present disclosure.

FIG. 10 illustrates measuring reflective visibility according to Experimental Examples and Example Embodiments of the present disclosure.

FIG. 11 illustrates surface treatment of an adhesive according to an example embodiment of the present disclosure.

FIG. 12 is a diagram for describing a curvature improvement of the adhesive according to an example embodiment of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Same reference numerals designate same elements throughout. Names of the respective elements used in the following explanations are selected only for convenience of writing the specification and can be thus different from those used in actual products.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. When “comprise,” “have,” and “include” described in the present specification are used, another part can be added unless “only” is used. The terms of a singular form can include plural forms unless referred to the contrary.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used. In the description of embodiments, when a structure is described as being positioned “on or above” or “under or below” another structure, this description should be construed as including a case in which the structures contact each other as well as a case in which a third structure is disposed therebetween.

In describing a temporal relationship, for example, when the temporal order is described as, for example, “after,” “subsequent,” “next,” and “before,” or the like a case that is not continuous can be included unless a more limiting term, such as “just,” “immediate(ly),” or “direct(ly)” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing the elements of the present disclosure, the terms “first,” “second,” “A,” “B,” “(a),” “(b),” etc., can be used. These terms are intended to identify the corresponding elements from the other elements, and basis, order, or number of the corresponding elements should not be limited by these terms. In case of the expression that an element is “connected,” “coupled,” or “adhered” to another element or layer, the element or layer can not only be directly connected or adhered to another element or layer, but also be indirectly connected or adhered to another element or layer with one or more intervening elements or layers disposed or interposed between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in co-dependent relationship.

In the present disclosure, examples of a display apparatus can include a narrow-sense display apparatus such as a quantum dot (QD) module, an organic light emitting diode (OLED) module or a liquid crystal module (LCM) having a display panel and a driver for driving the display panel. Further, examples of the display apparatus can include a set device (or a set apparatus) or a set electronic apparatus such as a notebook computer, a TV, a computer monitor, an equipment apparatus including an automotive apparatus or another type of apparatus for vehicles, or a mobile electronic device such as a smartphone or an electronic pad, which is a complete product (or a final product) including an LCM, an OLED module, and a QD module.

Therefore, in the present disclosure, examples of the display apparatus can include a narrow-sense display apparatus itself, such as an LCM, an OLED module, and a QD module, and a set device, which is a final consumer device or an application product including the LCM, the OLED module, and the QD module.

In some embodiments, an LCM, an OLED module, and a QD module including a display panel and a driver can be referred to as a narrow-sense display apparatus, and an electronic device, which is a final product including an LCM, an OLED module, and a QD module can be referred to as a set device. For example, the narrow-sense display apparatus can include a display panel, such an LCM, an OLED module, or a QD module, and a source printed circuit board (PCB), which is a controller for driving the display panel. The set device can further include a set PCB, which is a set controller electrically connected to the source PCB to overall control the set device.

A display panel applied to embodiments of the present disclosure can use any type of display panel, including a liquid crystal display panel, an organic light emitting diode (OLED) display panel, a quantum dot (QD) display panel, and an electroluminescent display panel. The display panel of the embodiment is not limited to a specific display panel capable of bezel bending with a flexible substrate for an organic light emitting diode (OLED) display panel and a lower back plate support structure. Further, a shape or a size of a display panel applied to a display apparatus according to these embodiments is not limited.

In an example where the display panel is the organic light emitting display panel, the display panel can include a plurality of gate lines, data lines, and pixels respectively provided in intersections of the gate lines and the data lines. Further, the display panel can include an array including a thin film transistor (TFT), which is an element for selectively applying a voltage to each of the pixels, a light emitting element layer on the array, and an encapsulation substrate or an encapsulation layer disposed on the array to cover the light emitting element layer. The encapsulation substrate can protect the TFT and the light emitting element layer from an external impact and can prevent water or oxygen from penetrating into the light emitting element layer. Further, a layer provided on the array can include an inorganic light emitting layer, for example, a nano-sized material layer, a quantum dot, or the like.

Features of various embodiments of the present disclosure can be partially or overall coupled to or combined with each other, and can be variously inter-operated with each other and driven technically. Embodiments of the present disclosure can be carried out independently from each other, or can be carried out together in co-dependent relationship.

Hereinafter, an example embodiment of the present disclosure will be described in detail with reference to the accompanying drawings. All the components of each display apparatus according to all embodiments of the present disclosure are operationally coupled and configured. Further, for convenience of description, a scale, size and thickness of each of elements illustrated in the accompanying drawings differs from a real scale, and thus, embodiments of the present disclosure are not limited to a scale illustrated in the drawings.

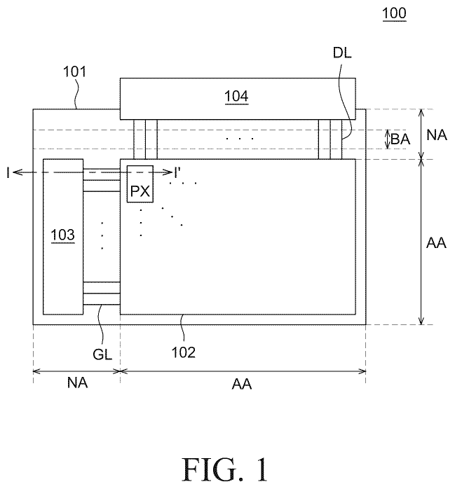

FIG. 1 illustrates a display apparatus according to an example embodiment of the present disclosure.

Referring to FIG. 1, a display apparatus 100 according to an example embodiment of the present disclosure can include a display panel 102. The display panel 102 can include a display area (or an active area) AA provided on a substrate 101 and a non-display area (or a non-active area) NA disposed on a periphery of the display area AA. The substrate 101 can be formed of, or include a plastic material having a flexibility so as to be bendable. For example, the substrate 101 can be constituted by materials such as polyimide (PI), polyethylene terephthalate (PET), polyethylene naphthalate (PEN), polycarbonate (PC), polyethersulfone (PES), polyarylate (PAR), polysulfone (PSF), and cyclo-olefin copolymer (COC), and example embodiments of the present disclosure are not limited thereto. For example, glass is not excluded as the material of the substrate 101. As another example embodiment of the present disclosure, the substrate 101 can be formed of, or include a semiconductor material such as a silicon wafer. Accordingly, in various embodiments of the present invention, the substrate 101 can be provided by various materials that are bendable, flexible, deflectable, or a combination of various materials having flexibility and rigidity.

The display area AA can be an area in which a plurality of subpixels PX is disposed and an image is displayed. Each of the plurality of subpixels PX can be individual units emitting light. A light emitting element and a driving circuit can be disposed at each of the plurality of subpixels PX. For example, a display element configured to display the image and a circuit part configure to drive the display element can be disposed at the plurality of subpixels PX. For example, when the display apparatus 100 is an organic light emitting display apparatus, the display element can include an organic light emitting element, and when the display apparatus 100 is a liquid crystal display apparatus, the display element can include a liquid crystal element. The plurality of subpixels PX can include a red subpixel PX, a green subpixel PX, a blue subpixel PX, and/or a white subpixel PX or the like, and example embodiments of the present disclosure are not limited thereto. In various embodiments of the present disclosure, the plurality of subpixels can be arranged into a pixel, and the display area AA can include a plurality of pixels including the sub pixels.

The non-display area NA can be an area in which the image is not displayed. The non-display area NA can be an area in which various wirings and driving ICs configured to drive the plurality of subpixels PX disposed in the display area AA are disposed. For example, at least any one of a data driving part 104 and a gate driving part 103 can be disposed at the non-display area NA, and example embodiments of the present disclosure are not limited thereto.

The non-display area NA can be an area surrounding or is adjacent the display area AA. For example, the non-display area NA can be at the periphery of the display area AA. For example, the non-display area NA can also be an area extended from the display area AA, and also be an area in which the plurality of subpixels PX is not disposed, and example embodiments of the present disclosure are not limited thereto.

The non-display area NA in which the image is not displayed can be a bezel area, or can further include a bending area BA in which the substrate 101 is bendable or is bent, and example embodiments of the present disclosure are not limited thereto.

A plurality of data lines DL and a plurality of gate lines GL can be disposed in or at the display area AA. For example, the plurality of data lines DL can be disposed in a row or column, and the plurality of gate lines GL can be disposed in the column or row. The subpixel PX can be disposed in an area constituted by the data line DL and/or the gate line GL.

The subpixel PX of the display area AA can include a thin film transistor or transistor configured by a semiconductor layer. For example, the thin-film transistor or the transistor can include an oxide semiconductor material, and example embodiments of the present disclosure are not limited thereto. For example, the thin-film transistor can be the transistor, and is not limited to a terminology or a description. Reference to not limited to a terminology means that an element needed not be defined by a particular term used to describe the element.

According to an example embodiment of the present disclosure, the gate driving part 103 including a gate driving circuit can be disposed in or at the non-display area NA. The gate driving circuit of the gate driving part 103 sequentially supplies a scan signal to the plurality of gate lines GL to sequentially drive respective pixel rows of the display area AA. For example, the pixel row can be a row constituted by pixels connected to one gate line. The gate driving circuit can also be a scan driving circuit, and is not limited to the terminology.

The gate driving circuit can be configured by a thin-film transistor having a polycrystal semiconductor layer, and also configured by a thin-film transistor having an oxide semiconductor layer, and also configured by making a pair by the thin-film transistor having the polycrystal semiconductor layer and the thin-film transistor having the oxide semiconductor layer. When the same semiconductor material is used in the thin-film transistors disposed in or at the non-display area NA and the display area AA, the thin film transistors can be simultaneously configured in the same process, and example embodiments of the present disclosure are not limited thereto.

The gate driving circuit can include a shift register and a level shifter.

The gate driving circuit can be implemented in the form of gate in panel (GIP) and can be directly disposed in or at the substrate 101 like the display apparatus 100 according to an example embodiment of the present disclosure.

The gate driving part 103 including the gate driving circuit can sequentially supply a scan signal of an on voltage or an off voltage to a plurality of gate lines.

The gate driving part 103 according to an example embodiment of the present disclosure can also be directly formed on the substrate 101 by a thin-film transistor using a polycrystal semiconductor material as a semiconductor layer, and also formed by configuring C-MOS with the thin-film transistor by the polycrystal semiconductor material as the semiconductor layer and the thin-film transistor by the oxide semiconductor material as the semiconductor layer.

For example, the oxide semiconductor material can include at least one or more of an InGaZnO (IGZO)-based oxide semiconductor material, an InZnO (IZO)-based oxide semiconductor material, an InGaZnSnO (IGZTO)-based oxide semiconductor material, an InSnZnO (ITZO)-based oxide semiconductor material, an FeInZnO (FIZO)-based oxide semiconductor material, a ZnO-based oxide semiconductor material, an SiInZnO (SIZO)-based oxide semiconductor material, and a Zn-Oxynitride (ZnON)-based oxide semiconductor material, and example embodiments of the present disclosure are not limited thereto, as other oxides or transparent conductive materials can be used.

When the thin-film transistor having the oxide semiconductor layer and the thin-film transistor having the polycrystal semiconductor layer are included, due to a high electron mobility in a channel area, it can be possible to implement with a high resolution and a low power consumption.

The display apparatus 100 according to an example embodiment of the present disclosure can further include the data driving part 104 including a data driving circuit. When a specific gate line is opened by the gate driving part 103 including the gate driving circuit, the data driving circuit converts image data into an analog type data voltage to supply the converted voltage to a plurality of data lines.

A plurality of gate lines GL disposed in the substrate 101 can include a plurality of scan lines and a plurality of light emitting control lines. The plurality of scan lines and the plurality of light emitting control lines can be wirings that deliver different types of gate signals (the scan signal and the light emitting control signal) to gate nodes of different types of transistors (a scan transistor and a light emitting control transistor) from each other.

The gate driving part 103 including the gate driving circuit can include a scan driving circuit that outputs scan signals to a plurality of scan lines which is one type of the gate line GL and a light emitting driving circuit that outputs light emitting control signals to a plurality of light emitting control lines which is another type of the gate line.

The display panel 102 according to an example embodiment of the present disclosure can further include a bending area BA in which the substrate 101 is bent. The bending area BA can be an area in which the substrate 101 is bendable and is bent when the display panel 102 or the display apparatus 100 is folded. The substrate 101 can be maintained in a flat state in an area other than the bending area BA. The data line DL can be disposed to pass through the bending area BA, and various data lines DL can be disposed and connected to a data pad. An area of the substrate 101 that is maintained in the flat state can still be bendable, but can be maintained in a flat state by a plate that supports the substrate 101. Alternatively, the area of the substrate 101 can be rigid, so that the plate is not needed. In embodiments of the present invention, the substrate 101 can be entirely bendable, or can have areas that are selectively bendable, and can be composed of different areas having flexibility, rigidity, or a combination of flexible and rigid areas.

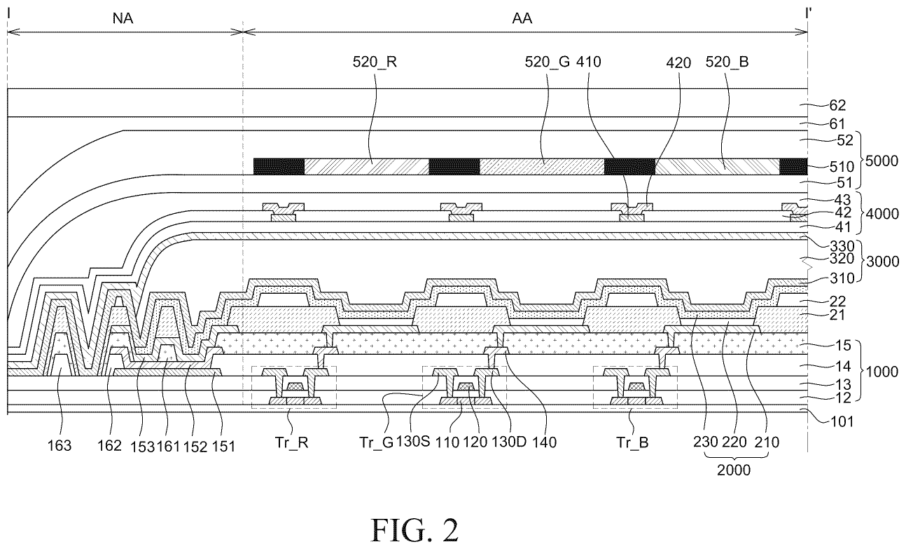

FIG. 2 is a cross-sectional view taken along the line I-I′ of FIG. 1 according to an example embodiment of the present disclosure.

Referring to FIG. 2, the display apparatus according to an example embodiment of the present disclosure can include a display area AA and a non-display area NA. The non-display area NA can be disposed at the periphery of the display area AA.

The substrate 101 can include a first substrate, a second substrate, and an intermediate layer between the first substrate and the second substrate, and example embodiments of the present disclosure are not limited thereto, as other substrates can be used.

For example, the first substrate and the second substrate can be formed of, or include at least one or more of polyimide, polyethersulfone, polyethylene terephthalate, and polycarbonate, and example embodiments of the present disclosure are not limited thereto, as other organic materials can be used. When the substrate 101 is formed of, or include a plastic material, a manufacturing process of the display apparatus can be conducted in a state that a support substrate formed of, or include glass is disposed below the substrate 101, and after the manufacturing process of the display apparatus is completed, the support substrate can be released. In addition, a back plate (or plate) for supporting the substrate 101 can be disposed below the substrate 101 after the support substrate is released. When the substrate 101 is formed of, or include the plastic material, moisture permeates into the substrate so that moisture permeation progresses up to a light emitting element layer of a transistor part or a light emitting part. As a consequence, the performance of the display apparatus can be deteriorated. The display apparatus according to an example embodiment of the present disclosure can be constituted by two substrates, i.e., a first substrate and a second substrate formed of, or include the plastic material to suppress the performance of the display apparatus from being deteriorated due to the moisture permeation. In addition, the intermediate layer which is an inorganic layer can be formed between the first substrate and the second substrate to block or prevent the permeation of the moisture into the substrate, thereby enhancing the reliability of the display apparatus. The intermediate layer can be configured by the inorganic layer. For example, the intermediate layer can be configured by a single layer of silicon nitride (SiNx) or silicon oxide (SiOx), or a plurality of layers thereof, and example embodiments of the present disclosure are not limited thereto, as other ceramics, organic or inorganic materials can be used. For example, the first substrate can be a multilayer structure in which a first polyimide film, the inorganic layer, and a second polyimide film are sequentially laminated or stacked.

The display apparatus disposed on the substrate 101 can include a plurality of areas. In the present disclosure, the display apparatus is constituted by the display area AA and the non-display area NA, and example embodiments of the present disclosure are not limited thereto.

A transistor part 1000, a light emitting part 2000, an encapsulation part 3000, a touch part 4000, and a color filter part 5000 can be disposed on the substrate 101, and example embodiments of the present disclosure are not limited thereto.

A first buffer layer (or buffer layer) can be disposed on one surface of the substrate 101 in the display area AA and the non-display area NA. As the first buffer layer, the buffer layer (or first buffer layer) can be disposed, which is configured by a single layer of silicon nitride (SiNx) or silicon oxide (SiOx), or a plurality of layers thereof. The buffer layer can serve to enhance adhesion force between layers formed on the buffer layer and the substrate 101, and serve to block or prevent various types of defects such as an alkali component which leaks from the substrate 101. The buffer layer can delay the diffusion of moisture and/or oxygen which have permeated into the substrate 101. The buffer layer can also be omitted based on the type and the material of the substrate, and the structure and the type of the thin-film transistor.

The transistor part 1000 can be on the substrate 101 and/or the buffer layer, and can be disposed in the display area AA and the non-display area NA. Transistors in the display area AA can include a switching transistor or a driving transistor configured to drive a subpixel. The transistor of the non-display area NA can include a gate driver, e.g., a transistor or a light emitting transistor configured to drive the GIP.

Referring to FIG. 2, a first driving transistor Tr_R, a second driving transistor Tr_G, and a third driving transistor Tr_B of the red (R), green (G), and blue (B) subpixels can be disposed in the display area AA.

Each of the first driving transistor Tr_R, the second driving transistor Tr_G, and the third driving transistor Tr_B can include a semiconductor layer 110, a gate electrode 120, a source electrode 130S, and a drain electrode 130D on the substrate 101 or the buffer layer. The semiconductor layer 110 can be formed of, or include low temperature poly silicone (LTPS) formed of, or including a polycrystal silicone or metal oxide. For example, the metal oxide can be configured by at least one or more of indium-gallium-zinc-oxide (IGZO), indium-zinc-oxide (IZO), indium-gallium-tin-oxide (IGTO), and indium-gallium-oxide (IGO), and example embodiments of the present disclosure are not limited thereto, as other oxides of other metals can be used.

The LPTS semiconductor layer can form a channel area, and a source area or a drain area connected to the source electrode or the drain electrode by an electron injection doping.

The metal oxide can enhance a conductive characteristic by a doping process of injecting impurities, and include a channel area in which a channel through which electrons or holes move is formed.

A first insulating layer 12 can be disposed on the semiconductor layer 110. Since the first insulating layer 12 is disposed between the semiconductor layer 110 and the gate electrode 120, the first insulating layer 12 can insulate the semiconductor layer 110 and the gate electrode 120. The first insulating layer 12 can be a gate insulating layer, and example embodiments of the present disclosure are not limited thereto.

The first insulating layer 12 can be formed of, or include an insulating inorganic material such as silicon nitride (SiNx) or silicon oxide (SiOx), and example embodiments of the present disclosure are not limited thereto. For example, the first insulating layer 12 can also be formed of, or include an insulating organic material.

The gate electrode 120 can be disposed to overlap the semiconductor layer 110. The gate electrode 120 can be formed by, or include a single layer or a plurality of layers formed of, or including any one of silver (Ag), molybdenum (Mo), copper (Cu), titanium (Ti), aluminum (Al), chromium (Cr), nickel (Ni), neodymium (Nd), tungsten (W), and gold (Au), or an alloy thereof, and example embodiments of the present disclosure are not limited thereto, as other metals or metal alloys can be used.

A second insulating layer 13 can be disposed on the gate electrode 120. The second insulating layer 13 can be an interlayer insulating layer, and example embodiments of the present disclosure are not limited thereto.

The second insulating layer 13 can be formed of, or include the insulating inorganic material such as silicon nitride (SiNx) or silicon oxide (SiOx), and example embodiments of the present disclosure are not limited thereto, as other ceramics, organic or inorganic materials can be used. For example, the second insulating layer 13 can be formed of, or include the insulating organic material.

The source electrode 130S and the drain electrode 130D can be disposed on the second insulating layer 13. The source electrode 130S and the drain electrode 130D can be connected to the semiconductor layer 110.

The source electrode 130S and the drain electrode 130D can be formed through the same process. The source electrode 130S and the drain electrode 130D can be formed of, or include at least one or more materials of silver (Ag), molybdenum (Mo), copper (Cu), titanium (Ti), aluminum (Al), chromium (Cr), nickel (Ni), neodymium (Nd), tungsten (W), and gold (Au), or an alloy thereof, and example embodiments of the present disclosure are not limited thereto, as other metals or metal alloys can be used. As another example, the source electrode 130S and the drain electrode 130D can be formed by, or include at least two layers including a first layer including titanium (Ti) and a second layer. The second layer can have at least one or more of molybdenum (Mo), copper (Cu), aluminum (Al), silver (Ag), chromium (Cr), gold (Au), neodymium (Nd), and nickel (Ni), and example embodiments of the present disclosure are not limited thereto, as other metals or metal alloys can be used.

When the source electrode 130S and the drain electrode 130D are formed, a first wiring 151 can be formed in the non-display area NA by the same process. As another example, the first wiring 151 can be formed in a different process from those of the source electrode 130S and the drain electrode 130D.

The first wiring 151 can deliver a low-potential voltage EVSS output from a flexible printed circuit board (FPCB) to a cathode electrode 230.

A first passivation layer 14 can be disposed on a part of the source electrode 130S and the drain electrode 130D, and the first wiring 151. The first passivation layer 14 can be a first planarization layer, and example embodiments of the present disclosure are not limited thereto.

The first passivation layer 14 can be formed of, or include an inorganic insulating layer such as silicon nitride (SiNx) or silicon oxide (SiOx), and an organic insulating layer such as polyacrylate and polyimide, and example embodiments of the present disclosure are not limited thereto.

A connection electrode 140 can be disposed on the first passivation layer 14, and the drain electrode 130D and an anode electrode 210 can be electrically connected through or via a contact hole formed in the first passivation layer 14.

The connection electrode 140 can be formed of, or include at least one or more materials of silver (Ag), molybdenum (Mo), copper (Cu), titanium (Ti), aluminum (Al), chromium (Cr), nickel (Ni), neodymium (Nd), tungsten (W), and gold (Au), or alloys thereof, and example embodiments of the present disclosure are not limited thereto. As another example, the connection electrode 140 can formed by, or include at least two layers including a first layer including titanium (Ti) and a second layer. The second layer has at least one or more of molybdenum (Mo), copper (Cu), aluminum (Al), silver (Ag), chromium (Cr), gold (Au), neodymium (Nd), and nickel (Ni), and example embodiments of the present disclosure are not limited thereto, as other metals or metal alloys can be used.

A second wiring 152 can be disposed in the non-display area NA in the same process of forming the connection electrode 140. The second wiring 152 can be connected to the first wiring 151 and can be used as an auxiliary electrode that transfers a voltage to the cathode electrode 230.

A second passivation layer 15 can be disposed on a part of the connection electrode 140 and the second wiring 152. The second passivation layer 15 can be a second planarization layer, and example embodiments of the present disclosure are not limited thereto.

Since the second passivation layer 15 is formed by, or include the organic insulating layer, a step difference by wirings and contact holes formed below the second passivation layer 15 can be reduced. For example, the organic insulating layer can be polyacrylate and polyimide or the like, and example embodiments of the present disclosure are not limited thereto.

The light emitting part 2000 can be disposed on the transistor part 1000. For example, the light emitting part 2000 can be disposed on the second passivation layer 15 of the display area AA. The light emitting part 2000 can include an anode electrode 210, a light emitting element layer 220, and a cathode electrode 230.

The anode electrode 210 can be electrically connected to the drain electrode 130D of the driving transistor through the connection electrode 140. The anode electrode 210 can be formed of, or include at least one or more of silver (Ag), aluminum (Al), gold (Au), molybdenum (Mo), tungsten (W), chromium (Cr), lead (Pd), indium tin oxide (ITO), and indium zinc oxide (IZO), or an alloy thereof, and example embodiments of the present disclosure are not limited thereto, as other conductive materials can be used.

A third wiring 153 can be disposed in the non-display area NA by the same process of forming the anode electrode 210. As another example, the third wiring 153 can be formed in a different process from that of the anode 210.

The third wiring 153 can be an auxiliary electrode that is interconnected to the second wiring 152 and the first wiring 151 to transfer the voltage to the cathode electrode 230, and example embodiments of the present disclosure are not limited thereto. As another example, at least one or more of the second wiring 152 and the third wiring 153 can be omitted.

A bank 21 can be disposed on a part of the anode electrode 210 and the third wiring 153.

The bank 21 can divide a plurality of subpixels, and can minimize a glare phenomenon, and prevent or reduce color mixing which occurs in various viewing angles. The bank 21 can exposes the anode electrode 210 corresponding to the light emitting area, and can overlap an end portion of the anode electrode 210. The bank 21 can overlap holes formed in the second insulating layer 13 and the first passivation layer 14 and contact holes formed in the second passivation layer 15.

The bank 21 can be formed of, or include at least one or more materials of the inorganic insulating material such as silicon nitride (SiNx) and silicon oxide (SiOx) or an organic insulating material such as benzocyclobutene (BCB), acryl resin, epoxy resin, phenolic resin, polyamide resin, and polyimide resin, and example embodiments of the present disclosure are not limited thereto, as other insulating materials can be used. As another example, the bank 21 can be formed by, or include a black bank to which a black pigment is added for reducing light reflection, and example embodiments of the present disclosure are not limited thereto.

A spacer 22 can be further disposed on the bank 21. The spacer 22 buffers an empty space between the substrate 101 in which the light emitting element layer 220 is formed and an upper substrate, to minimize the display apparatus from being damaged from an impact from the outside. The spacer 22 can be formed of, or include a same material as the bank 21, and formed simultaneously with the bank 21, and example embodiments of the present disclosure are not limited thereto.

The light emitting element layer 220 can be disposed on an opening portion of the bank 21 that exposes the anode electrode 210. The light emitting element layer 220 can include at least one or more of a red light emitting layer, a green light emitting layer, a blue light emitting layer, and a white light emitting layer, and example embodiments of the present disclosure are not limited thereto.

When the light emitting element layer 220 includes a white organic light emitting layer emitting the white light, the light emitting element layer 220 can be disposed in or at the opening portion of the bank 21 and an entire of the substrate.

The cathode electrode 230 can be disposed on the light emitting element layer 220. The cathode electrode 230 can supply electrons to the light emitting element layer 220. For example, the cathode electrode 230 can be formed of, or include a conductive material having a low work function, and example embodiments of the present disclosure are not limited thereto.

When the display apparatus is one using a top emission scheme, the cathode electrode 230 can be formed by a transparent conductive material transmitting light. For example, the cathode electrode 230 can be formed of, or include at least one or more of indium tin oxide (ITO) and indium zinc oxide (IZO), and example embodiments of the present disclosure are not limited thereto.

For example, the cathode electrode 230 can be formed of, or include a translucent conductive material transmitting light. For example, the cathode electrode 230 can be formed of, or include at least one or more of alloys such as LiF/Al, CsF/Al, Mg:Ag, Ca/Ag, Ca:Ag, LiF/Mg:Ag, LiF/Ca/Ag, and LiF/Ca:Ag, and example embodiments of the present disclosure are not limited thereto.

When the display apparatus is one using a bottom emission scheme, the cathode electrode 230 can be formed by an opaque conductive material as a reflective electrode that reflects light. For example, the cathode electrode 230 can be formed of, or include at least one or more of silver (Ag), aluminum (Al), gold (Au), molybdenum (Mo), tungsten (W), and chromium (Cr), or an alloy thereof, and example embodiments of the present disclosure are not limited thereto, as other materials can be used.

The light emitting element layer 220 can further include a hole injection layer, a hole transport layer, an electron transport layer, and an electron injection layer in addition to the light emitting layer, and example embodiments of the present disclosure are not limited thereto.

For example, the light emitting element layer 220 can be formed by laminating a hole transfer layer, the light emitting layer, and an electron transfer layer in this order or in a reverse order on the anode electrode 210. For example, the hole transfer layer can be a layer that injects or transfers holes into the light emitting layer. For example, the hole transfer layer can be the hole injection layer, the hole transport layer, and an electron blocking layer, and example embodiments of the present disclosure are not limited thereto. The electron transfer layer can be a layer that injects or transfers electrons into the light emitting layer. For example, the electron transfer layer can be the electron transport layer, the electron injection layer, and a hole blocking layer, and example embodiments of the present disclosure are not limited thereto.

The light emitting element layer 220 can include one light emitting part. One light emitting part can include a red light emitting layer, a green light emitting layer, and a blue light emitting layer that emit red light, green light, and blue light, respectively, for each subpixel PX.

The light emitting element layer 220 can include two or more light emitting parts. The light emitting part can be expressed as a stack, and is not limited to the terminology. Two or more light emitting parts can include a first light emitting part and a second light emitting part. The first light emitting part and the second light emitting part can include the red light emitting layer, the green light emitting layer, and the blue light emitting layer that emit red light, green light, and blue light, respectively, for each subpixel. Two or more light emitting layers included in the first light emitting part and the second light emitting part can be light emitting layers that emit the same color. As another example, the first light emitting layer included in the first light emitting part can be the blue light emitting layer, a sky blue light emitting layer, a dark blue light emitting layer, the blue light emitting layer and the red light emitting layer, the sky blue light emitting layer and the red light emitting layer, and the dark blue light emitting layer and the red light emitting layer, and example embodiments of the present disclosure are not limited thereto. For example, the second light emitting layer included in the second light emitting part can be a yellow light emitting layer, a yellow-green light emitting layer, the green light emitting layer, the yellow light emitting layer and the red light emitting layer, the yellow-green light emitting layer and the red light emitting layer, the green light emitting layer and the red light emitting layer, a combination of the yellow light emitting layer, the yellow-green light emitting layer, and the green light emitting layer, a combination of the yellow light emitting layer, the yellow-green light emitting layer, the green light emitting layer, and the red light emitting layer, a combination of two yellow-green light emitting layers and one green light emitting layer, a combination of one yellow-green light emitting layer and two green light emitting layers, a combination of two yellow-green light emitting layers, one green light emitting layer, and the red light emitting layer, and a combination of one yellow-green light emitting layer, two green light emitting layers, and the red light emitting layer, and the example embodiments of the present disclosure are not limited thereto. A charge generation layer can be configured between the first light emitting part and the second light emitting part. The charge generation layer can include an n-type charge generation layer and a p-type charge generation layer. Each of the first light emitting part and the second light emitting part can include at least one or more of a hole injection layer, a hole transport layer, a hole blocking layer, an electron blocking layer, an electron transport layer, and an electron injection layer, and example embodiments of the present disclosure are not limited thereto.

Two or more light emitting parts can include a first light emitting part, a second light emitting part, and a third light emitting part. The first light emitting layer included in the first light emitting part can be the same as described above. The second light emitting layer included in the second light emitting part can be the same as described above. The third light emitting layer included in the third light emitting part can be configured to be the same as the first light emitting layer, and example embodiments of the present disclosure are not limited thereto. A first charge generation layer can be configured between the first light emitting part and the second light emitting part. The first charge generation layer can include an n-type charge generation layer and a p-type charge generation layer. A second charge generation layer can be configured between the second light emitting part and the third light emitting part. The second charge generation layer can include an n-type charge generation layer and a p-type charge generation layer. Each of the first light emitting part, the second light emitting part, and the third light emitting part can include at least one of a hole injection layer, a hole transport layer, a hole blocking layer, an electron blocking layer, an electron transport layer, and an electron injection layer, and example embodiments of the present disclosure are not limited thereto.

Two or more or light emitting parts can include the first light emitting part, the second light emitting part, the third light emitting part, and a fourth light emitting part. At least two or more light emitting layers of the first light emitting part, the second light emitting part, the third light emitting part, and the fourth light emitting part can be configured by light emitting layers that emit the same color. For example, at least two or more light emitting layers of the first light emitting part, the second light emitting part, the third light emitting part, and the fourth light emitting part can be configured by the blue light emitting layer, and example embodiments of the present disclosure are not limited thereto. At least one or more light emitting layers of the first light emitting part, the second light emitting part, the third light emitting part, and the fourth light emitting part can include the blue light emitting layer and another light emitting layer. For example, at least one or more light emitting layers in the first light emitting part, the second light emitting part, the third light emitting part, and the fourth light emitting part can be the yellow light emitting layer, the yellow-green light emitting layer, the green light emitting layer, the yellow light emitting layer and the red light emitting layer, the yellow-green light emitting layer and the red light emitting layer, the green light emitting layer and the red light emitting layer, the combination of the yellow light emitting layer, the yellow-green light emitting layer, and the green light emitting layer, the combination of the yellow light emitting layer, the yellow-green light emitting layer, the green light emitting layer, and the red light emitting layer, the combination of two yellow-green light emitting layers and one green light emitting layer, the combination of one yellow-green light emitting layer and two green light emitting layers, the combination of two yellow-green light emitting layers, one green light emitting layer, and the red light emitting layer, and the combination of one yellow-green light emitting layer, two green light emitting layers, and the red light emitting layer, and example embodiments of the present disclosure are not limited thereto. The first charge generation layer can be configured between the first light emitting part and the second light emitting part. The first charge generation layer can include an n-type charge generation layer and a p-type charge generation layer. The second charge generation layer can be configured between the second light emitting part and the third light emitting part. The second charge generation layer can include an n-type charge generation layer and a p-type charge generation layer. A third charge generation layer can be configured between the third light emitting part and the fourth light emitting part. The third charge generation layer can include an n-type charge generation layer and a p-type charge generation layer. Each of the first light emitting part, the second light emitting part, the third light emitting part, and the fourth light emitting part can include at least one or more of a hole injection layer, a hole transport layer, a hole blocking layer, an electron blocking layer, an electron transport layer, and an electron injection layer, and example embodiments of the present disclosure are not limited thereto.

In the non-display area NA of the display apparatus, an end portion including the driving circuit part and a dam part in which a plurality of dams is disposed can be provided. The end portion of the non-display area NA can be an area where the display apparatus is sealed by a connection part where the cathode electrode 230 and an EVSS line are electrically connected, and the encapsulation layer and the plurality of dams. At the end portion, the first insulating layer 12, the second insulating layer 13, the first passivation layer 14, and the second passivation layer 15 disposed on the substrate 101 can be extended and disposed.

Wirings can be disposed at the end portion so that a power voltage and touch signals applied in the FPCB of the display apparatus are connected through the wirings.

The plurality of dams can be disposed at the end portion of the non-display area NA. To suppress a phenomenon in which the second encapsulation layer 320 formed by, or include an organic layer among the plurality of dams is leaked or overflowed to the outside, one or more insulating layers can be laminated and formed, and example embodiments of the present disclosure are not limited thereto.

The plurality of dams can include a first dam 161, a second dam 162, and a third dam 163, and include at least two or more dams, and embodiments are not limited to the number of dams. Each of the first dam 161, the second dam 162, and the third dam 163 can surround or be adjacent to the display area AA.

The first dam 161, the second dam 162, and the third dam 163 can have a first height, a second height, and a third height, respectively. For example, the second height can be higher than the first height, and the third height can be lower than the second height.

Even though the second encapsulation layer 320 goes beyond the first dam 161, the phenomenon in which the second encapsulation layer 320 is leaked or overflowed to the outside can be prevented or reduced by the second dam 162.

The first dam 161, the second dam 162, and the third dam 163 can be constituted by at least one of the first passivation layer 14, the second passivation layer 15, the bank 21, and the spacer 22.

The first wiring 151 can be disposed below the second passivation layer 15 constituting the first dam 161 and the first passivation layer 14 constituting the second dam 162. The second wiring 152 can be disposed between the second passivation layer 15 and the bank 21 constituting the first dam 161 and the second dam 162. The third wiring 153 can be disposed on the bank 21 of the first dam 161.

The first wiring 151, the second wiring 152, and the third wiring 153 can be contacted with each other and electrically connected in areas of the first dam 161 and the second dam 162 to transfer the voltage to the cathode electrode 230.

The first wiring 151, the second wiring 152, and the third wiring 153 can be disposed to overlap a part of the gate driver of the driving circuit part. For example, the gate driver can be a gate-in panel (GIP), and example embodiments of the present disclosure are not limited thereto.

A capping layer can be disposed on the cathode electrode 230. The capping layer can protect the cathode electrode 230 and can enhance external light efficiency. For example, the capping layer can be configured by the organic layer and/or an inorganic layer. For example, the capping layer can be formed of, or include a metallic material such as lithium fluoride (LiF), etc., as the inorganic layer, and can be formed to further include the organic layer, and example embodiments of the present disclosure are not limited thereto.

An encapsulation part 3000 can be disposed on the light emitting part 2000. For example, the encapsulation part 3000 can be disposed on the cathode electrode 230 and the capping layer. The encapsulation part 3000 can protect the display apparatus from moisture, oxygen, or foreign objects from the outside. For example, since the encapsulation part 3000 suppresses the permeation of the oxygen and the moisture from the outside, the encapsulation part 3000 can prevent oxidation of light emitting materials and electrode materials.

The encapsulation part 3000 can be formed of, or include a transparent material so that light emitted by the light emitting element layer 220 is transmitted.

The encapsulation part 3000 can include a first encapsulation layer 310, a second encapsulation layer 320, and a third encapsulation layer 330, and example embodiments of the present disclosure are not limited thereto. The first encapsulation layer 310, the second encapsulation layer 320, and the third encapsulation layer 330 can have a structure in which the encapsulation layers are sequentially stacked, and example embodiments of the present disclosure are not limited thereto.

The first encapsulation layer 310 and the third encapsulation layer 330 can be formed of, or include at least one material of silicon nitride (SiNx), silicon oxide (SiOx), or aluminum oxide (AlyOz), and example embodiments of the present disclosure are not limited thereto, as other insulating materials can be used.

The second encapsulation layer 320 can cover foreign materials or particles which can be generated in the manufacturing process. The second encapsulation layer 320 can planarize the surface of the first encapsulation layer 310.

The second encapsulation layer 320 can be an organic material, for example, a polymer such as a silicon oxy carbon (SiOCz) epoxy, a polyimide, a polyethylene, and an acrylate based material, and example embodiments of the present disclosure are not limited thereto.

A touch part 4000 for a touch operation on the display apparatus 100 can be disposed on the third encapsulation layer 330.

The touch part 4000 can be disposed between the encapsulation part 3000 and a color filter part 5000. For example, in the touch part 4000, a buffer layer (or a second buffer layer) 41 can be disposed on the third encapsulation layer 330. The buffer layer 41 can enhance an adhesion force between layers formed on the buffer layer 41 and the third encapsulation layer 330. The buffer layer 41 can be extended up to an area where the connection part of the flexible PCB (FPCB) disposed in the non-display area NA and the substrate 101 is disposed. The buffer layer 41 can be configured by a single layer of silicon nitride (SiNx) or silicon oxide (SiOx), or a plurality of layers thereof, and example embodiments of the present disclosure are not limited thereto.

A bridge electrode 410 can be disposed on the buffer layer 41. The bridge electrode 410 can electrically connect touch electrodes 420 and can transfer a touch signal. The bridge electrode 410 can be formed by, or include a single layer or a plurality of layers formed of, or including any one of silver (Ag), molybdenum (Mo), copper (Cu), titanium (Ti), aluminum (Al), chromium (Cr), nickel (Ni), neodymium (Nd), tungsten (W), and gold (Au), or an alloy thereof, and example embodiments of the present disclosure are not limited thereto.

A third insulating layer 42 can be disposed on the bridge electrode 410. The third insulating layer 42 can connect the touch electrodes 420 which are spaced apart to the bridge electrode 410 through a contact hole formed on the third insulating layer 42. For example, since the third insulating layer 42 can be an insulating layer disposed in or at the touch part 4000, the third insulating layer 42 can be a touch insulating layer, and example embodiments of the present disclosure are not limited thereto. For example, the third insulating layer 42 can be configured by a single layer of silicon nitride (SiNx) or silicon oxide (SiOx), or a plurality of layers thereof, and example embodiments of the present disclosure are not limited thereto.

The touch electrode 420 can be disposed on the third insulating layer 42. The touch electrode 420 can be connected to a plurality of touch lines disposed in or at the non-display area NA and can be connected to a touch circuit in the flexible PCB (FPCB).

The touch circuit can supply a touch driving signal to the touch electrode 420 to drive the touch operation, detect a touch sensing signal from the touch electrode 420, and can sense whether a touch is formed or not and/or a touch location (coordinate) based on the touch sensing signals.

The touch electrode 420 can be formed by, or include a single layer or a plurality of layers formed of, or including any one of silver (Ag), molybdenum (Mo), copper (Cu), titanium (Ti), aluminum (Al), chromium (Cr), nickel (Ni), neodymium (Nd), tungsten (W), and gold (Au), or an alloy thereof, and example embodiments of the present disclosure are not limited thereto. For example, the touch electrode 420 and the bridge electrode 410 can be disposed at locations corresponding to the bank 21 and the spacer 22.

A third passivation layer 43 and a fourth passivation layer 51 can be disposed on the touch electrode 420.

The third passivation layer 43 and the fourth passivation layer 51 can be extended up to an area where the connection part of the flexible PCB (FPCB) disposed in the non-display area NA and the substrate 101 is disposed.

The third passivation layer 43 and the fourth passivation layer 51 can be formed of, or include at least one or more materials of the inorganic insulating material such as silicon nitride (SiNx) or silicon oxide (SiOx), or an organic insulating material such as a benzocyclobutene (BCB), an acryl resin, an epoxy resin, a phenolic resin, a polyamide resin, or a polyimide resin, and example embodiments of the present disclosure are not limited thereto.

Color filters 520_R, 520_G, and 520_B and a black matrix 510 can be disposed on the fourth passivation layer 51. For example, the color filters 520_R, 520_G, and 520_B and the black matrix 510 can be disposed to correspond to the subpixels PX.

In the display apparatus according to an example embodiment of the present disclosure, an optical control layer is not configured, and the color filter part 5000 can be disposed on the touch part 4000. For example, the optical control layer can be a polarizer. Since the polarizer can prevent or reduce light incident from the outside of the display panel from being touched and reflected on the cathode electrode 230 between the subpixels PX, the visibility of the display apparatus can be enhanced. However, when the light passes through the polarizer, the brightness is reduced by approximately 50% or more, so there is a problem in that light efficiency is lowered. Therefore, since more current should be applied to the light emitting part 2000 in order to implement a display apparatus having a desired brightness, there is a problem in that the power consumption increases. To solve the problem, the polarizer is not disposed, and the color filter part 5000 can be disposed. Thus, a display apparatus having a low power consumption and a thin thickness can be provided.

The display apparatus can further include a protection layer 52 on the color filters 520_R, 520_G, and 520_B, and the black matrix 510. For example, the protection layer 52 can be formed of, or include at least one or more materials of the inorganic insulating material such as silicon nitride (SiNx) or silicon oxide (SiOx), or an organic insulating material such as polyacrylate or polyimide, and example embodiments of the present disclosure are not limited thereto. For example, the protection layer 52 can extend to the non-display area NA. An adhesive layer 61 can be disposed on the protection layer 52. For example, the adhesive layer 61 can be disposed over the color filter part 5000. A cover window 62 can be disposed over the color filter part 5000. The adhesive layer 61 can be disposed between the protection layer 52 and the cover window 62. For example, the adhesive layer 61 can be disposed between the color filter part 5000 and the cover window 62. For example, the cover window 62 can be attached on the color filter part 5000 by the adhesive layer 61. For example, the adhesive layer 61 can be formed of, or include an optically cleared adhesive (OCA) and/or an optically cleared resin (OCR), etc., and example embodiments of the present disclosure are not limited thereto. For example, the protection layer 52 can be a passivation layer or a fifth passivation layer, and example embodiments of the present disclosure are not limited thereto. For example, the cover window 62 can be a window cover, a cover member, or a front member, and example embodiments of the present disclosure are not limited thereto.

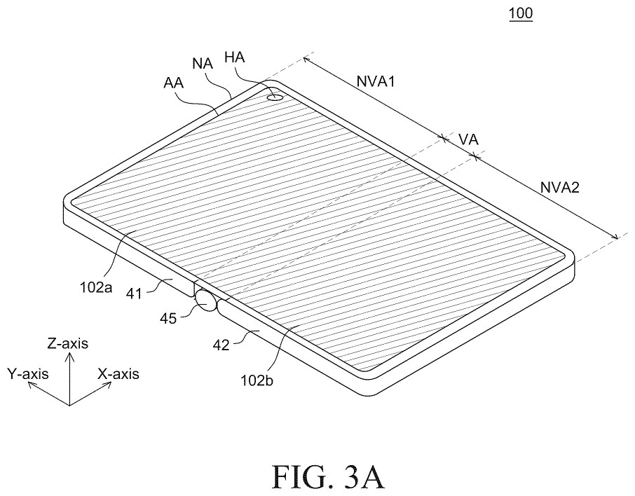

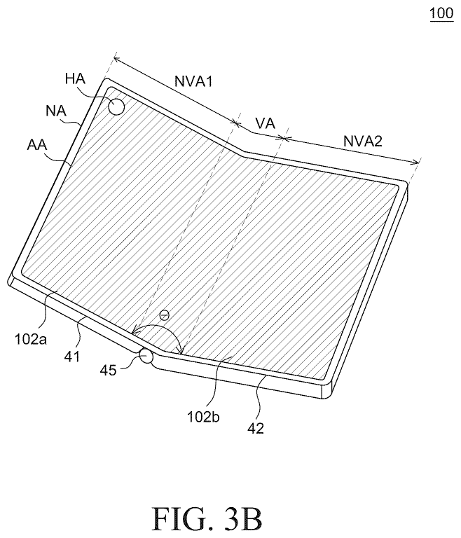

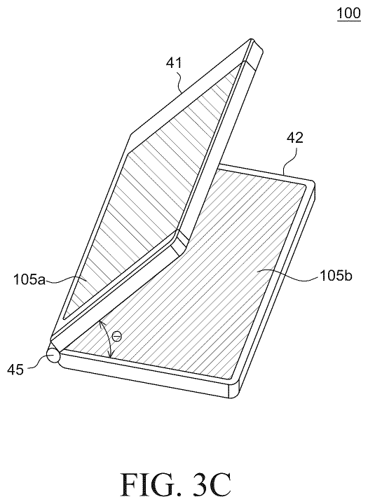

FIGS. 3A to 3C are perspective views of a display apparatus according to an example embodiment of the present disclosure.

Referring to FIGS. 3A to 3C, the display apparatus 100 according to an example embodiment of the present disclosure can include a display area AA, a non-display area NA, and a hole area HA.

The display area AA can be an area in which the image is displayed. The non-display area NA can be an area which is disposed at the periphery of, or adjacent to the display area AA and in which the image is not displayed.

The display apparatus 100 can include a variable area VA and non-variable areas NVA1 and NVA2 based on whether a variation occurs. For example, the variation can include folding, bending, or being flexible, and example embodiments of the present disclosure are not limited thereto. For example, the variation can include all structures including a structure in which the display apparatus 100 is fully folded to a structure in which the display apparatus 100 can be bent at the level of several nanometers. For example, the display apparatus 100 can include a variable area VA and non-variable areas NVA1 and NVA2 based on whether folding or bending occurs or not. The display apparatus 100 can include a foldable display apparatus, a bendable display apparatus, a curved display apparatus, a variable display apparatus, or a flexible display apparatus, and the example embodiments of the present disclosure are not limited thereto. Here, in regard to the display apparatus 100, a folding apparatus is described as an example, and example embodiments of the present disclosure are not limited thereto.

The variable area VA can be an area folded when folding the display apparatus 100. For example, the variable area VA can be a folding area. For example, the variable area VA can be folded according to a specific curvature radius based on a folding axis Fx. For example, the folding axis Fx of the variable area VA can be formed in an X-axis direction, and the non-variable areas NVA1 and NVA2 can be extended from the variable area VA in a Y-axis direction which is perpendicular to the folding axis Fx. When the variable area VA is folded based on the folding axis Fx, the variable area VA can form a part of a circle or ellipse. The curvature radius of the variable area VA can be a radius of the circle or ellipse formed by, or include the variable area VA, and example embodiments of the present disclosure are not limited thereto.

The non-variable areas NVA1 and NVA2 can be areas which are not folded when folding the display apparatus 100. For example, the non-variable areas NVA1 and NVA2 can maintain a plane state when folding the display apparatus 100. The non-variable areas NVA1 and NVA2 can be disposed at opposite sides of the variable area VA, and example embodiments of the present disclosure are not limited thereto. For example, the non-variable areas NVA1 and NVA2 can be areas which are extended in the Y-axis direction based on the folding axis Fx. In this case, the variable area VA can be disposed between the non-variable areas NVA1 and NVA2. For example, when the display apparatus 100 is folded based on the folding axis Fx, the non-variable areas NVA1 and NVA2 can overlap each other. For example, the non-variable areas NVA1 and NVA2 can overlap a part of the display area AA and a part of the non-display area NA.

For example, when an upper surface on which the image is displayed is referred to as a display surface in the display apparatus 100, and a lower surface of the display apparatus 100 which is an opposite surface to the display surface is referred to as a back surface, the variable area VA can be folded by one of an outer folding scheme in which the display surface of the display apparatus 100 is folded to be exposed to the outside or an inner folding scheme in which the display surfaces of the display apparatus 100 are folded to face each other, and example embodiments of the present disclosure are not limited thereto.

For example, the variable area VA can be an area which is bent with a predetermined curvature radius when the display apparatus 100 is folded by at least one scheme of inner folding and outer folding. An area other than the non-variable areas NVA1 and NVA2 can be the variable area VA.

The display apparatus 100 can further include a case that supports and stores the display panel, etc., and a hinge structure for folding the display panel. The variable area VA and the non-variable areas NVA1 and NVA2 can also be applied the same to the layer components of the display apparatus 100, and each layer of the display apparatus 100 can include a variable area VA and non-variable areas NVA1 and NVA2.

Referring to FIGS. 3A to 3C, the display apparatus 100 can include a first housing 41 and a second housing 42. The first housing 41 and the second housing 42 can be coupled by a connection member 45 to be pivotably connected. For example, the connection member 45 can be formed on or at a side surface of the first housing 41. The connection member 45 can be formed on or at the side surface of the second housing 42. A hinge or the connection member 45 formed on the side surface of the first housing 41 is coupled to the connection member 45 formed on or at the side surface of the second housing 42 to be pivotably connected. The connection member 45 can include the hinge, and example embodiments of the present disclosure are not limited thereto. According to another example embodiment, the connection member 45 can be formed integrally with the first housing 41 or the second housing 42.

Referring to FIG. 3B, a scheme in which display surfaces 102a and 102b of the display apparatus 100 are folded to face each other is illustrated. For example, a lower surface of the first housing 41 and an upper surface of the second housing 42 can have an unfolding state to be unfolded to be positioned on one plane with respect to the connection member 45. Referring to FIG. 3C, the first housing 41 and the second housing 42 can have a folding state to face each other with respect to on the connection member 45, and a state in which the first housing 41 and the second housing 42 are unfolded at a predetermined angle is illustrated. An angle θ formed by the first housing 41 and the second housing 42 can be a right angle or an obtuse angle, and example embodiments of the present disclosure are not limited thereto.

A display surface 105a corresponding to the display area AA can be exposed to the outside in a state in which the display apparatus 100 is folded. For example, the display apparatus 100 can activate the display area AA corresponding to the display surface 105a in the state in which the display apparatus 100 is folded. A display surface 105b can be deactivated. Activation can be, or refer to displaying a screen corresponding to the display area AA. Alternatively, activation can be, or refer to displaying the screen in a partial area of the display area AA. Alternatively, activation can be, or refer to supplying a power to a subpixel or pixel corresponding to the display area AA to display the screen. Alternatively, activation can be, or refer to changing from a sleep state to an active state. Display areas AA corresponding to an edge of the first housing 41 and an edge of the second housing 42 can be deactivated. Deactivation can be, or refer to turning off the screen corresponding to the display area AA. Alternatively, deactivation can be, or refer to not supplying the power to the subpixel or pixel corresponding to the display area AA to display the screen. Alternatively, deactivation can be, or refer to a state in which the display apparatus 100 changes from the active state to the sleep state.

According to another example embodiment of the present disclosure, the display surface 105a corresponding to the display area AA can be exposed to the outside in the state in which the display apparatus 100 is folded. For example, the display apparatus 100 can activate the display area AA corresponding to the display surface 105a in the state in which the display apparatus 100 is folded. A display surface 105b can be activated in the state in which the display apparatus 100 is unfolded. The display surface 105a and the display surface 105b can be interlocked to display the same display surface, and example embodiments of the present disclosure are not limited thereto.

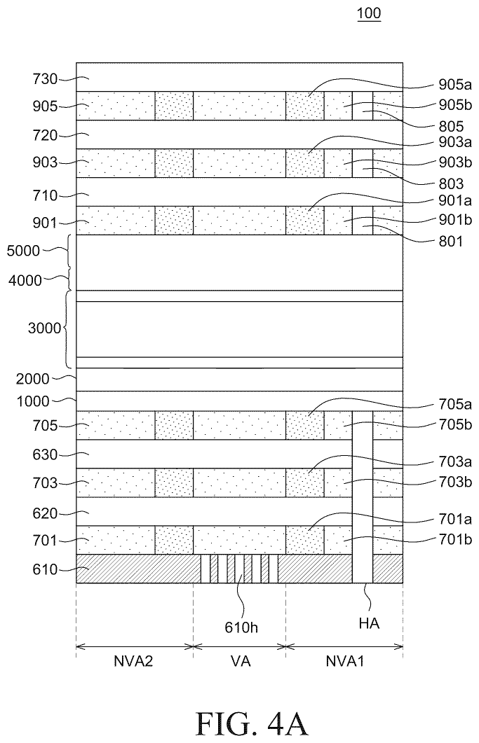

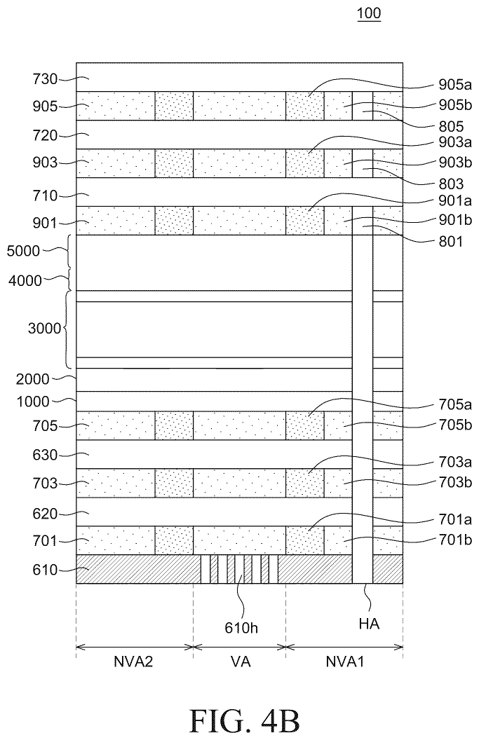

FIG. 4A illustrates a display apparatus according to an example embodiment of the present disclosure. FIG. 4B illustrates a display apparatus according to another example embodiment of the present disclosure.

Referring to FIGS. 2 to 4A and 4B, the display apparatus 100 according to an example embodiment of the present disclosure can include a transistor part 1000, a light emitting part 2000, an encapsulation part 3000, a touch part 4000, and a color filter part 5000, and embodiments of the present disclosure are not limited thereto.

The transistor part 1000 can be disposed on a substrate 101. The light emitting part 2000 can be disposed on the transistor part 1000. The encapsulation part 3000 can be disposed on the light emitting part 2000. The touch part 4000 and the color filter part 5000 can be disposed on the encapsulation part 3000. The transistor part 1000, the light emitting part 2000, the encapsulation part 3000, the touch part 4000, and the color filter part 5000 are substantially the same as described in FIG. 2, so a description thereof can be omitted or will be briefly given. The display panel can include the transistor part 1000, the light emitting part 2000, the encapsulation part 3000, the touch part 4000, and the color filter part 5000, and example embodiments of the present disclosure are not limited thereto.

A display panel having a flexibility can be difficult to maintain a shape of the display panel in a predetermined form (or shape), and the display panel can be vulnerable to an external stimulus when the display apparatus 100 is folded or bent. Therefore, various types of support members can be disposed on a rear surface of the display panel or the transistor part 1000. For example, at least one or more plates can be disposed below the display panel or the transistor part 1000. For example, a first plate 610, a second plate 620, and a third plate 630 can be disposed below the display panel or the transistor part 1000, and example embodiments of the present disclosure are not limited thereto. For example, the transistor part 1000 can be disposed on at least one or more plates.

For example, when the substrate 101 formed of, or including the plastic material is applied, a thickness of the substrate 101 is small, so the display panel can be drooped upon folding or bending. To supplement the sagging of the display panel, the third plate 630 can be disposed on the rear surface of the transistor part 1000. For example, the third plate 30 can be a back plate or a support plate, and is not limited to the terminology.

The first plate 610 can reinforce a rigidity (or a stiffness) of the substrate 101 formed of, or including the plastic material and the second plate 620. The first plate 610 can be formed of, or include a metal having excellent thermal conductivity. For example, the first plate 610 can be formed of, or include metallic materials such as stainless steel (SUS), carbon fiber reinforced plastics (CFRP), invar, aluminum (Al), and magnesium (Mg), etc., and example embodiments of the present disclosure are not limited thereto. For example, since the metallic materials have a larger strength than the plastic material, the durability of the display apparatus 100 can be further enhanced.

The first plate 610 can include at least one or more opening patterns (or opening portions) 610h. For example, at least one or more opening patterns 610h can correspond to the variable area VA of the display apparatus 100. At least one or more opening patterns 610h allows the first plate 610 of the variable area VA to be easily folded, and can effectively alleviate a stress applied to the first plate 610 upon folding. Further, at least one or more opening patterns 610h facilitate restoration after folding to enhance a folding characteristic of the display apparatus 100.

At least one or more opening patterns 610h can be extended in a parallel direction to the folding axis Fx, and can be configured in a discontinuous form. A length of each of one or more opening patterns 610h can be shorter than a width in the folding axis Fx direction of the first plate 610. A shape and a disposition scheme of at least one or more opening patterns 610h are not limited to the illustrated shape and disposition scheme. Intervals (or distances) of one or more opening patterns 610h adjacent to each other in a perpendicular direction to the folding axis Fx can be constant, and example embodiments of the present disclosure are not limited thereto. For example, one or more opening patterns 610h can be configured in a constant form, and example embodiments of the present disclosure are not limited thereto. For example, one or more opening patterns 610h can be formed in different shapes or at different intervals (or distances) in the variable area VA, and example embodiments of the present disclosure are not limited thereto. For example, the interval (or distance) of one or more opening patterns 610h adjacent to each other in the direction perpendicular to the folding axis Fx can be wider as the farther the one or more opening patterns 610h are from the folding axis Fx. One or more opening patterns 610h adjacent to each other in the direction perpendicular to the folding axis Fx can have a first interval at a central portion adjacent to the folding axis Fx, and a second interval larger than the first interval at both or opposite edge portions (or both or opposite periphery portions) of the central portion. For example, one or more opening patterns 610h can have a circular shape of a rectangle, a rectangular shape, a rhombus shape, and a circular shape, and example embodiments of the present disclosure are not limited thereto.

The second plate 620 can be disposed on the first plate 610. For example, the second plate 620 can reinforce the rigidity (or the stiffness) of the display panel and/or the transistor part 1000. The second plate 620 can be formed of, or include a different material from the first plate 610. The second plate 620 can be formed of, or include a polymer that blocks ultraviolet ray. For example, the second plate 620 can be formed of, or include black polyethylene terephthalate (PET), and example embodiments of the present disclosure are not limited thereto. The first plate 610 can be a lower plate and the second plate 620 can be an upper plate, and is not limited to the terminology.

At least one or more adhesives can be disposed in or at the display area AA. For example, at least one or more adhesives can be disposed between one or more plates. For example, the one or more adhesives can include a first adhesive 701, a second adhesive 703, and a third adhesive 705, and example embodiments of the present disclosure are not limited thereto. The first adhesive 701 can be disposed between the first plate 610 and the second plate 620. The second adhesive 703 can be disposed between the second plate 620 and the third plate 630. The third adhesive 705 can be disposed between the third plate 630 and the transistor part 1000. For example, the first adhesive 701 can cover one or more opening patterns 610h of the first plate 610. For example, the first adhesive 701 to the third adhesive 705 can be simply three of the third adhesives or even one or more of the third adhesives, and so the various adhesives are not limited to the terminology.

The first adhesive 701, the second adhesive 703, and the third adhesive 705 can be formed of, or include an optically cleared adhesive (OCA), and an optically cleared resin (OCR), etc.

Referring to FIGS. 4A and 4B, one or more cover members can be disposed on the color filter part 5000. The one or more cover members can include a first cover member 710, a second cover member 720, and a third cover member 730, and example embodiments of the present disclosure are not limited thereto. For example, the cover member can be a front member, a cover window, or a window cover, and example embodiments of the present disclosure are not limited thereto.

One or more cover members can be disposed on the color filter part 5000. For example, the first cover member 710 can be disposed on the color filter part 5000. The second cover member 720 can be disposed on the first cover member 710. The third cover member 730 can be disposed on the second cover member 720. For example, at least one or more of the first cover member 710, the second cover member 720, and the third cover member 730 can protect the display apparatus not to be damaged by an external impact or not to be deteriorated by moisture, oxygen, or foreign particles from the outside.

At least one or more of the first cover member 710, the second cover member 720, and the third cover member 730 can be formed of, or include materials which are transparent, and have excellent impact-resistance and scratch-resistance. For example, at least one or more of the first cover member 710, the second cover member 720, and the third cover member 730 can be configured by a film formed of, or including polyimide, polyamide, polyethylene terephthalate, polymethylmethacrylate, propylene glycol, and polycarbonate, and example embodiments of the present disclosure are not limited thereto. As another example, at least one or more of the first cover member 710, the second cover member 720, and the third cover member 730 can be configured by a film formed of, or including optically isotropic polymers such as cyclo olefin (co)polymer, optically isotropic polycarbonate, and optically isotropic polymethylmethacrylate, etc., and example embodiments of the present disclosure are not limited thereto. As another example, at least one or more of the first cover member 710, the second cover member 720, and the third cover member 730 can be configured by chemically strengthened thin-film glass.

When the third cover member 730 is configured by the thin-film glass, a protective film for preventing or reducing scattering can be disposed on the third cover member 730.

Referring to FIG. 4A, the display apparatus 100 according to an example embodiment of the present disclosure can include the hole area HA. The hole area HA can be disposed on or at the periphery of, or adjacent to the display area AA. The hole area HA can be disposed on or at the periphery of the substrate 101.

For example, the hole area HA can be on a part of at least one or more plates and a part of at least one or more cover members. For example, the hole area HA can be on a part of at least one or more plates among the first plate 610, the second plate 620, and the third plate 630, and a part of at least one or more cover members among the first cover member 710, the second cover member 720, and the third cover member 730. For example, the hole area HA which is on at least one or more plates among the first plate 610, the second plate 620, and the third plate 630 can be formed as an empty space, and example embodiments of the present disclosure are not limited thereto, as the hole area HA can be filled with either completely or partially with a clear or transparent material. The display apparatus in which the hole area HA of FIG. 4A is disposed can be referred to as under display panel (UDC), and is not limited to the terminology. For example, the display area of the hole area HA can be configured in a sparse structure, and can be a structure which can receive light from the outside by a camera which is in the hole area HA. For example, at least one or more of the camera, a sensor, and an optical part can be disposed in or at the hole area HA, and example embodiments of the present disclosure are not limited thereto. For example, the sensor can be an infrared sensor, and example embodiments of the present disclosure are not limited thereto.

Referring to FIG. 4B, the hole area HA can be on or at from a part of at least one or more plates to a part of at least one or more cover members. For example, the hole area HA can be from a part of at least one or more plates among the first plate 610, the second plate 620, and the third plate 630 to a part of at least one or more cover members among the first cover member 710, the second cover member 720, and the third cover member 730. For example, the hole area HA which is on at least one or more plates among the first plate 610, the second plate 620, and the third plate 630, and the color filter part 5000 is formed as an empty space. The display apparatus in which the hole area HA of FIG. 4B is disposed can be referred to as hole in display (HID), and is not limited to the terminology. For example, at least one or more of the camera, a sensor, and an optical part can be disposed in or at the hole area HA, and example embodiments of the present disclosure are not limited thereto. For example, the sensor can be an infrared sensor, and example embodiments of the present disclosure are not limited thereto.

Referring to FIGS. 4A and 4B, one or more adhesives can be disposed in or at the display area AA. For example, at least one or more adhesives can be disposed between the one or more cover members. For example, at least one or more adhesives can be disposed in or at the display area AA and can be disposed between one or more cover members. The one or more adhesives can include a fourth adhesive 901, a fifth adhesive 903, and a sixth adhesive 905, and example embodiments of the present disclosure are not limited thereto. For example, the fourth adhesive 901 can be disposed between the color filter part 5000 and the first cover member 710. For example, the fifth adhesive 903 can be disposed between the first cover member 710 and the second cover member 720. For example, the sixth adhesive 905 can be disposed between the second cover member 720 and the third cover member 730. The fourth adhesive 901 to the sixth adhesive 905 can be one or more first adhesives, and are not limited to the terminology.

The fourth adhesive 901, the fifth adhesive 903, and the sixth adhesive 905 can be formed of, or include the optically cleared adhesive (OCA), and the optically cleared resin (OCR), or the like.

Referring to FIGS. 4A and 4B, one or more adhesives can be disposed in or at the hole area HA. The one or more adhesives can include a seventh adhesive 801, an eighth adhesive 803, and a ninth adhesive 805, and example embodiments of the present disclosure are not limited thereto. The seventh adhesive 801 can be disposed between the color filter part 5000 and the first cover member 710. For example, the seventh adhesive 801 can be disposed in or at the hole area HA between the color filter part 5000 and the first cover member 710. The eighth adhesive 803 can be disposed between the first cover member 710 and the second cover member 720. For example, the eighth adhesive 803 can be disposed in or at the hole area HA between the first cover member 710 and the second cover member 720. The ninth adhesive 805 can be disposed between the second cover member 720 and the third cover member 730. For example, the ninth adhesive 805 can be disposed in or at the hole area HA between the second cover member 720 and the third cover member 730. The seventh adhesive 801 to the ninth adhesive 805 can be one or more second adhesives, and are not limited to the terminology.

The seventh adhesive 801, the eighth adhesive 803, and the ninth adhesive 805 can be formed of, or include the optically cleared adhesive (OCA), and the optically cleared resin (OCR), or the like. For example, since the at least one or more of the seventh adhesive 801, the eight adhesive 803, and the ninth adhesive 805 in or at the hole area HA is configured by a transparent adhesive to be configured to be transmitted by light from the outside.

When the first adhesive 701, the second adhesive 703, and the third adhesive 705 are configured by a transparent adhesive, there is a problem in that the reflectance of the display apparatus is lowered. When the fourth adhesive 901, the fifth adhesive 903, and the sixth adhesive 905 are configured by a transparent adhesive, there is the problem in that the reflectance of the display apparatus is lowered. Furthermore, since the display apparatus configured without the polarizer has no ultraviolet ray blocking function, the light emitting part should be protected from the ultraviolet rays. Therefore, the inventors of the present disclosure conducted various experiments that can enhance the reflectance of the display apparatus, and block the ultraviolet rays. Through various experiments, a new display apparatus was invented, which can enhance the reflectance of the display apparatus, and block the ultraviolet rays from the outside. This will be described below.

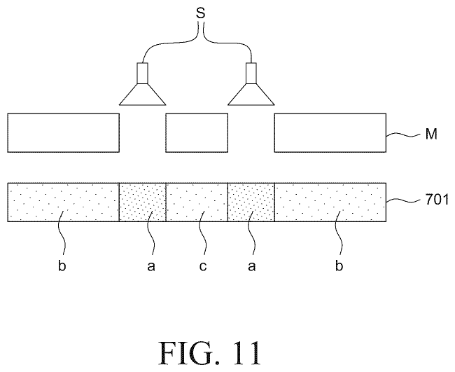

A first area 701a and a second area 701b of the first adhesive 701, a first area 703a and a second area 703b of the second adhesive 703, and a first area 705a and a second area 705b of the third adhesive 705 in FIGS. 4A and 4B will be described below with reference to FIG. 11. In addition, a first area 901a and a second area 901b of the fourth adhesive 901, a first area 903a and a second area 903b of the fifth adhesive 903, and a first area 905a and a second area 905b of the sixth adhesive 905 will be described later with reference to FIG. 11.

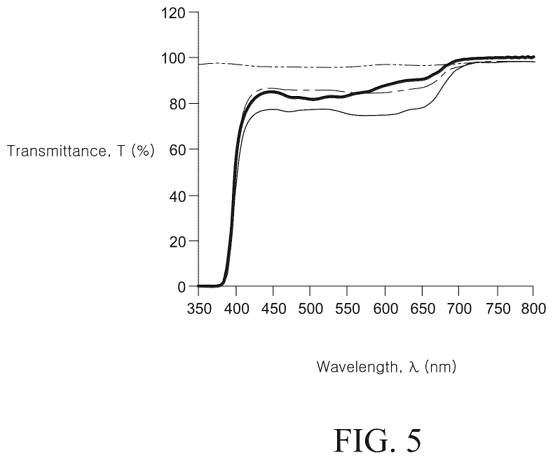

FIG. 5 illustrates transmittance of adhesives according to Example Embodiments of the present disclosure and Experimental Examples.

FIG. 5 illustrates an average transmittance of adhesives at a wavelength of 360 nm to 740 nm. In FIG. 5, a horizontal axis represents a wavelength (λ) (unit: nm), and a vertical axis represents a transmittance (T) (unit: %). A two-dot chain line represents a transparent adhesive that is an adhesive according to Experimental Example. A solid line, an alternated long and short dash line, and a thick solid line represent adhesives according to Example Embodiments of the present disclosure. The solid line represents an adhesive having a transmittance of 70% to 75%. The alternated long and short dash line represents an adhesive having a transmittance of 75% to 80%. The thick solid line represents an adhesive having a transmittance of 75% to 80%. Accordingly, in various embodiments of the present disclosure, the transmittance of an adhesive can be less than 97%, for example, less than 95%, less than 90%, less than 85% and others.

Referring to FIG. 5, it can be seen that the adhesive in the two-dot chain line has an average transmittance of about 97% at a wavelength of 360 nm to 740 nm. The adhesives in the solid line, the alternated long and short dash line, and the thick solid line can improve a reflectance by lowering the transmittance at the wavelength of 360 nm to 740 nm. For example, it can be seen that the adhesives in the solid line, the alternated long and short dash line, and the thick solid line have the transmittances of 70% or more and 80% or less at the wavelength of 360 nm to 740 nm. In addition, since the adhesives are configured to have the transmittance of 10% or less at a wavelength of 380 nm, it is possible to block ultraviolet rays from the outside. Accordingly, it is possible to provide a display apparatus having improved light resistance (or lightfast).

The adhesives according to Examples of the present disclosure can have the transmittance of 70% to 80% at a wavelength of 380 nm to 740 nm, and the transmittance of 10% or less at a wavelength of 380 nm. The adhesive according to an example embodiment of the present disclosure can be a gray adhesive or the like, and is not limited to the terms.

The adhesives in the solid line, the alternated long and short dash line, and the thick solid line can be at least one or more of the first adhesive 701 to the sixth adhesive 905 according to an example embodiment of the present disclosure.

According to an example embodiment of the present disclosure, at least one or more of the first adhesive 701, the second adhesive 703, and the third adhesive 705 can be configured as adhesive having the transmittance of 80% or less. For example, at least one or more of the first adhesive 701, the second adhesive 703, and the third adhesive 705 can have the transmittance of 70% or more and 80% or less.

According to an example embodiment of the present disclosure, at least one or more of the fourth adhesive 901, the fifth adhesive 903, and the sixth adhesive 905 can be configured as adhesives having the transmittance of 80% or less. For example, at least one or more of the fourth adhesive 901, the fifth adhesive 903, and the sixth adhesive 905 can have the transmittance of 70% or more and 80% or less.

According to an example embodiment of the present disclosure, at least one or more of the first adhesive 701, the second adhesive 703, the third adhesive 705, the fourth adhesive 901, the fifth adhesive 903, and the sixth adhesive 905 can be configured as adhesives having the transmittance of 80% or less. For example, at least one or more of the first adhesive 701, the second adhesive 703, the third adhesive 705, the fourth adhesive 901, the fifth adhesive 903, and the sixth adhesive 905 can have the transmittance of 70% or more and 80% or less.

According to an example embodiment of the present disclosure, at least one or more adhesives in or at the hole area HA can be different from at least one or more adhesives in or at the display area. For example, at least one or more of the seventh adhesive 801, the eighth adhesive 803, and the ninth adhesive 805 in or at the hole area HA can be different from at least one or more of the first adhesive 701, the second adhesive 703, and the third adhesive 705 in or at the display area AA. For example, the transmittance of at least one or more of the seventh adhesive 801, the eighth adhesive 803, and the ninth adhesive 805 in or at the hole area HA can be different from the transmittance of at least one or more of the first adhesive 701, the second adhesive 703, and the third adhesive 705 in the display area AA. For example, at least one or more of the seventh adhesive 801, the eighth adhesive 803, and the ninth adhesive 805 in or a t the hole area HA can have the transmittance of 97%. For example, at least one or more of the first adhesive 701, the second adhesive 703, and the third adhesive 705 in or at the display area AA can have the transmittance of 70% or more and 80% or less.

According to an example embodiment of the present disclosure, at least one or more adhesives in or at the hole area HA can be different from at least one or more adhesives in or at the display area. For example, at least one or more of the seventh adhesive 801, the eighth adhesive 803, and the ninth adhesive 805 in or at the hole area HA can be different from at least one or more of the fourth adhesive 901, the fifth adhesive 903, and the sixth adhesive 905 in or at the display area AA. For example, the transmittance of at least one or more of the seventh adhesive 801, the eighth adhesive 803, and the ninth adhesive 805 in or at the hole area HA can be different from the transmittance of at least one or more of the fourth adhesive 901, the fifth adhesive 903, and the sixth adhesive 905 in or at the display area AA. For example, at least one or more of the seventh adhesive 801, the eighth adhesive 803, and the ninth adhesive 805 in or at the area HA can have the transmittance of 97%. For example, at least one or more of the fourth adhesive 901, the fifth adhesive 903, and the sixth adhesive 905 in or at the display area AA can have the transmittance of 70% or more and 80% or less.

According to an example embodiment of the present disclosure, at least one or more adhesives in or at the hole area HA can be different from at least one or more adhesives in or at the display area. For example, at least one or more of the seventh adhesive 801, the eighth adhesive 803, and the ninth adhesive 805 in or at the hole area HA can be different from at least one or more of the first adhesive 701, the second adhesive 703, the third adhesive 705, the fourth adhesive 901, the fifth adhesive 903, and the sixth adhesive 905 in or at the display area AA. For example, the transmittance of at least one or more of the seventh adhesive 801, the eighth adhesive 803, and the ninth adhesive 805 in or at the hole area HA can be different from the transmittance of at least one or more of the first adhesive 701, the second adhesive 703, the third adhesive 705, the fourth adhesive 901, the fifth adhesive 903, and the sixth adhesive 905 in or at the display area AA. For example, at least one or more of the seventh adhesive 801, the eighth adhesive 803, and the ninth adhesive 805 in the area HA can have the transmittance of 97%. For example, at least one or more of the first adhesive 701, the second adhesive 703, the third adhesive 705, the fourth adhesive 901, the fifth adhesive 903, and the sixth adhesive 905 in the display area AA can have the transmittance of 70% or more and 80% or less. Accordingly, since the transmittance of the adhesive in or at the display area AA and the transmittance of the adhesive in or at the hole area HA are configured to be different from each other, it is possible to improve the reflective visibility in the display area AA and maintain the transmittance of the hole area HA.

In various embodiments of the present disclosure, reference to an adhesive with a transmittance of less than 97%, including the transmittance of 70% or more and 80% or less, can refer to the adhesive having a reflectance of 3% or greater, including the reflectance of 30% or less and 20% or more.

According to an example embodiment of the present disclosure, a plurality of first adhesives can be divided into or include a first group and a second group. For example, the first group of the plurality of first adhesives can be disposed between the one or more plates. For example, the first group of the plurality of first adhesives can include at least one of the first adhesive 701, the second adhesive 703, and the third adhesive 705. For example, the second group of the plurality of first adhesives can be disposed between the one or more cover members. For example, the second group of the plurality of first adhesives can include at least one of the fourth adhesive 901, the fifth adhesive 903, and the sixth adhesive 905. The first group of the plurality of first adhesives can have a first transmittance. The second group of the plurality of first adhesives can have a second transmittance different from the first transmittance. For example, the one or more second adhesives can include at least one of the seventh adhesive 801, the eighth adhesive 803, and the ninth adhesive 805 in or at the hole area HA. The one or more second adhesives can have a third transmittance. For example, the third transmittance can be different from the first transmittance. For example, the third transmittance can be different from the second transmittance.

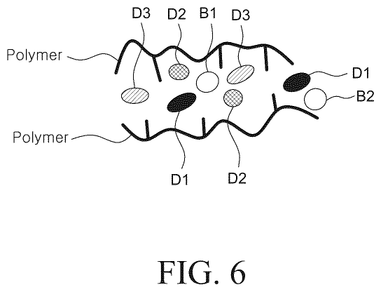

FIG. 6 illustrates an adhesive according to an example embodiment of the present disclosure.

Referring to FIG. 6, an adhesive according to an example embodiment of the present disclosure can be configured with a polymer. For example, the polymer can be a flexible polymer resin, and example embodiments of the present disclosure are not limited thereto. For example, the polymer can be acryl or epoxy, and example embodiments of the present disclosure are not limited thereto.

The polymer can include a color material and UV blockers B1 and B2. For example, the color material can include a pigment and a dye. For example, the dye can include one or more colors. The one or more colors can include red, yellow, and blue, and example embodiments of the present disclosure are not limited thereto. For example, the dye can include a red dye D1, a yellow dye D2, and a blue dye D3, but example embodiments of the present disclosure are not limited thereto.

For example, the UV blockers B1 and B2 can be hydroxybenzophenon, or hydroxybenzotriazole, and example embodiments of the present disclosure are not limited thereto.

For example, based on 100 wt % of the adhesive, the UV blockers B1 and B2 can be contained in an amount of 0.01 wt % to 5 wt %, and example embodiments of the present disclosure are not limited thereto. For example, based on 100 wt % of the adhesive, the dye can be contained in an amount of 0.01 wt % to 15 wt %, and example embodiments of the present disclosure are not limited thereto.

The adhesive according to an example embodiment of the present disclosure includes the color material and the UV blockers B1 and B2, thereby blocking ultraviolet rays while having the colors. Accordingly, since the light emitting part can be protected from ultraviolet rays from the outside, the performance and/or reliability of the display apparatus can be improved. In addition, since the adhesive according to an example embodiment of the present disclosure can control the amount of the dye, the transmittance and/or reflective visibility of the adhesive can be adjusted.

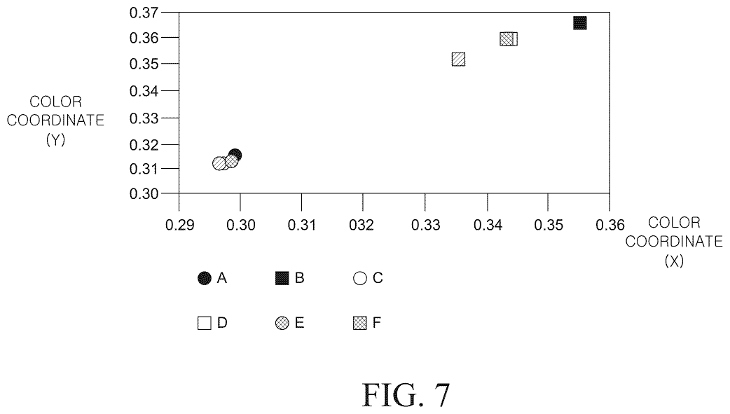

FIG. 7 illustrates a color coordinate according to an example embodiment of the present disclosure.

In FIG. 7, a horizontal axis represents an X value of the color coordinate, and a vertical axis represents a Y value of the color coordinate.

In FIGS. 7, A and B are configured in FIG. 4A or 4B and do not have a UV blocking function. For example, the UV blocking function can be a function that does not transmit light in an ultraviolet region of 380 nm or less. The first adhesive 701 to the sixth adhesive 905 are configured as transparent adhesives. A represents before evaluation of light resistance, and B represents after evaluation of light resistance. The light resistance is measured at 0.8 W (watt) for 240 hours at a temperature of 35° C. and a humidity of 55%, and example embodiments of the present disclosure are not limited to this measurement method.

The color coordinate of A is (0.2993, 0.3146) and the color coordinate of B is (0.3554, 0.3650). The color coordinate was measured at room temperature using CA-310 manufactured by Konica Minolta.

C and D are configured as UV blocking films instead of the third cover member 730 of FIG. 4A or 4B. For example, the UV blocking film can be a film that does not transmit light in an ultraviolet region of 380 nm or less. The first adhesive 701 to the sixth adhesive 905 are configured as transparent adhesives. The color coordinate of C is (0.2973, 0.3114) and the color coordinate of D is (0.3442, 0.3590). The color coordinate was measured in the same manner as in A and B. E and F are configured as UV blockers which are the fourth adhesive 901 of FIG. 4A or 4B. The color coordinate of E is (0.2988, 0.3123) and the color coordinate of F is (0.3435, 0.3588). The color coordinate was measured in the same manner as in A and B. The adhesive constituting the UV blocker is not intended to limit the content of the present disclosure.

According to an example embodiment of the present disclosure, it can be seen that when the adhesive including the UV blocker is configured, a change in color coordinate before and after evaluation of light resistance is small. For example, it can be seen that a change in color coordinates of A and B is (0.0561, 0.0504), and a change in color coordinates of C and D is (0.0469, 0.0476). For example, it can be seen that a change in color coordinates of E and F is (0.0447, 0.0465). Accordingly, when the adhesive is configured by including the UV blocker, the change in color coordinates before and after evaluation of light resistance or the distortion in color coordinates is small, and thus, a display apparatus with improved color coordinates can be provided.

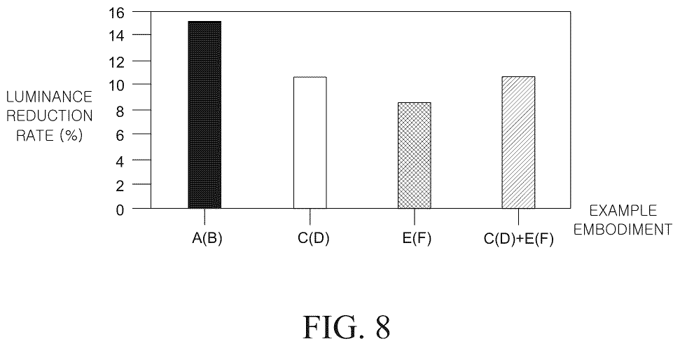

FIG. 8 illustrates a luminance according to an example embodiment of the present disclosure.

In FIG. 8, a horizontal axis represents Example Embodiments, and a vertical axis represents a luminance reduction rate (%). Since A, C, and E of the horizontal axis are configured in the same manner as in FIG. 7, the descriptions can be omitted herein. On the horizontal axis, A represents A and B, C represents C and D, and E represents E and F. C+E configures a UV blocking film of C and D, and configures the adhesive including the UV blocker of E and F. The luminance was measured using CA-310 manufactured by Konica Minolta, and example embodiments of the present disclosure are not limited thereto.

In FIG. 8, the luminance before evaluation of A and B was 449.8, the luminance after evaluation was 382.1, and the luminance reduction rate was measured to be −15.0%. The luminance before evaluation of C and D was 442.4, the luminance after evaluation was 395.5, and the luminance reduction rate was measured to be −10.6%. The luminance before evaluation of E and F was 441.4, the luminance after evaluation was 403.5, and the luminance reduction rate was measured to be −8.6%. The luminance before evaluation of C and D and E and F was 434.5, the luminance after evaluation was 387.6, and the luminance reduction rate was measured to be −10.8%.

According to an example embodiment of the present disclosure, it can be seen that when the adhesive including the UV blocker is configured, the luminance reduction rates before and after evaluation of light resistance are improved. As a result, it can be seen that since the luminance is improved, the performance and/or reliability of the display apparatus is improved.

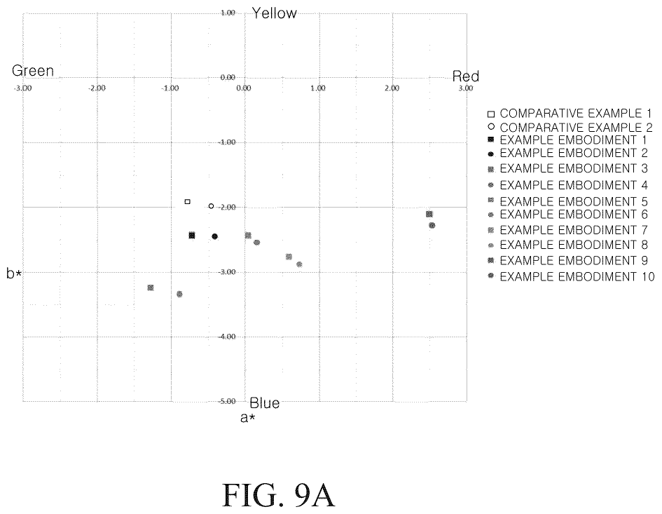

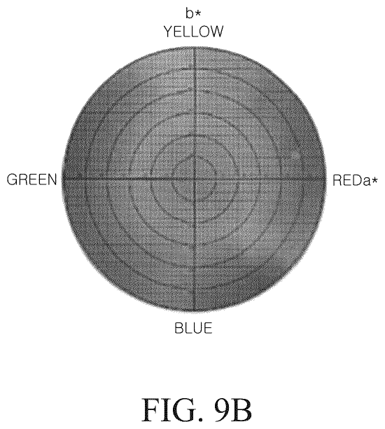

FIG. 9A illustrates the reflective visibility according to Example Embodiments of the present disclosure and Comparative Examples. FIG. 9B illustrates a color coordinate for explaining the reflective visibility according to an example embodiment of the present disclosure.

In FIG. 9A, the horizontal axis is indicated as a* in FIG. 9B, and the vertical axis is indicated as b* in FIG. 9B. For example, as a* is closer to (+), the red color is indicated, and as a* is closer to (−), the green color is indicated. For example, as b* is closer to (+), the yellow color is indicated, and as b* is closer to (−), the blue color is indicated. The reflective visibility was measured in a state in which the display apparatus was not driven.

Comparative Examples 1 and 2 in FIG. 9A are configured up to the color filter part 5000 in FIG. 4A or 4B. Example Embodiments 1 and 2 of the present disclosure are configured by adhesives having the transmittance of 70% to 75%. The ratio of the blue dye, the red dye, and the yellow dye included in the adhesives of Example Embodiments 1 and 2 of the present disclosure can be 4:1:2, and example embodiments of the present disclosure are not limited thereto. Example Embodiments 3 and 4 of the present disclosure are configured by adhesives having the transmittance of 75% to 80%. The ratio of the blue dye, the red dye, and the yellow dye included in the adhesives of Example Embodiments 3 and 4 of the present disclosure can be 4:1:2, and example embodiments of the present disclosure are not limited thereto. Example Embodiments 5 and 6 of the present disclosure are configured by adhesives having the transmittance of 70% to 80%. The ratio of the blue dye, the red dye, and the yellow dye included in the adhesives of Example Embodiments 5 and 6 of the present disclosure can be 4:3:2, and example embodiments of the present disclosure are not limited thereto. Example Embodiments 7 and 8 of the present disclosure are configured by adhesives having the transmittance of 70% to 80%. The ratio of the blue dye, the red dye, and the yellow dye included in the adhesives of Example Embodiments 7 and 8 can be 4:4:1, and example embodiments of the present disclosure are not limited thereto. Example Embodiments 9 and 10 of the present disclosure are configured by adhesives having the transmittance of 70% to 80%. The ratio of the blue dye, the red dye, and the yellow dye included in the adhesives of Example Embodiments 9 and 10 of the present disclosure can be 0:1:0, and example embodiments of the present disclosure are not limited thereto.

Table 1 shows a reflectance ratio as shown in FIG. 9A.

TABLE 1

| | Comparative | Example | Example | Example | Example | Example |
|---|---|---|---|---|---|---|
| | Examples 1 | Embodiments | Embodiments | Embodiments | Embodiments | Embodiments |
| Item | and 2 | 1 and 2 | 3 and 4 | 5 and 6 | 7 and 8 | 9 and 10 |
| Reflectance ratio | 6.94 | 5.59 | 6.00 | 5.64 | 5.57 | 5.72 |
| (SCI) (%) | | | | | | |
| Reflectance ratio | 1.03 | 0.66 | 0.83 | 0.66 | 0.61 | 0.65 |
| (SCE) (%) | | | | | | |
| Reflective | −0.77 | −0.57 | −1.09 | 0.10 | 0.67 | 2.51 |
| visibility (a*) | | | | | | |
| Reflective | −3.62 | −2.44 | −3.29 | −2.49 | −2.82 | −2.20 |
| visibility (b*) | | | | | | |

In Table 1, since Comparative Example 1 to Example Embodiment 10 of the present disclosure are the same as those described in FIG. 9A, the descriptions can be omitted herein. In addition, the values of reflectance ratio and reflective visibility represent an average value of Comparative Examples 1 and 2, an average value of Example Embodiments 1 and 2 of the present disclosure, an average value of Example Embodiments 3 and 4 of the present disclosure, an average value of Example Embodiments 5 and 6 of the present disclosure, an average value of Example Embodiments 7 and 8 of the present disclosure, and an average value of Example Embodiments 9 and 10 of the present disclosure. In addition, the reflectance ratio measurement can include SCI (Specular Component Included) and SCE (Specular Component Excluded). The reflectance ratio SCI is a reflectance value including both specularly reflected light and diffusely reflected light. The reflectance ratio SCE is a reflectance value of the diffusely reflected light excluding the specularly reflected light. The reflectance ratio and the reflective visibility of Table 1 can be values measured by a colorimeter CM2600, but are not limited thereto.

Referring to Table 1, it was measured that the average of the reflectance ratio (SCI) of Comparative Examples 1 and 2 was 6.94%, the average of the reflectance ratio (SCI) of Example Embodiments 1 and 2 of the present disclosure was 5.59%, and the average of the reflectance ratio (SCI) of Example Embodiments 3 and 4 of the present disclosure was 6.00%. It was measured that the average of the reflectance ratio (SCI) of Example Embodiments 5 and 6 of the present disclosure was 5.64%, the average of the reflectance ratio (SCI) of Example Embodiments 7 and 8 of the present disclosure was 5.57%, and the average of the reflectance ratio (SCI) of Example Embodiments 9 and 10 of the present disclosure was 5.72%. It can be seen that since Example Embodiments 1 to 10 of the present disclosure constitute adhesives having a lower transmittance than Comparative Examples 1 and 2 of the present disclosure, the reflectance of Example Embodiments 1 to 10 of the present disclosure is lower than that of Comparative Examples 1 and 2.

It was measured that the average of the reflectance ratio (SCE) of Comparative Examples 1 and 2 was 1.03%, the average of the reflectance ratio (SCE) of Example Embodiments 1 and 2 of the present disclosure was 0.66%, and the average of the reflectance ratio (SCE) of Example Embodiments 3 and 4 of the present disclosure was 0.83%. It was measured that the average of the reflectance ratio (SCE) of Example Embodiments 5 and 6 of the present disclosure was 0.66%, the average of the reflectance ratio (SCE) of Example Embodiments 7 and 8 of the present disclosure was 0.61%, and the average of the reflectance ratio (SCE) of Example Embodiments 9 and 10 of the present disclosure was 0.65%. It can be seen that since Example Embodiments 1 to 10 of the present disclosure constitute adhesives having a lower transmittance than Comparative Examples 1 and 2, the reflectance of Example Embodiments 1 to 10 of the present disclosure is lower than that of Comparative Examples 1 and 2.

It was measured that the average of reflective visibility (a*) of Comparative Examples 1 and 2 was −0.77, the average of reflective visibility (a*) of Example Embodiments 1 and 2 of the present disclosure was −0.57, and the average of reflective visibility (a*) of Example Embodiments 3 and 4 of the present disclosure was −1.09. It was measured that the average of reflective visibility (a*) of Comparative Example Embodiments 5 and 6 of the present disclosure was 0.10, the average of reflective visibility (a*) of Example Embodiments 7 and 8 of the present disclosure was 0.67, and the average of reflective visibility (a*) of Example Embodiments 9 and 10 was 2.51. Since the average of the reflective visibility (a*) of Example Embodiments 1 and 2 of the present disclosure and Example Embodiments 3 and 4 of the present disclosure is close to (−) as compared with the average of the reflective visibility (a*) of Example Embodiments 5 and 6 of the present disclosure, Example Embodiments 7 and 8 of the present disclosure, and Example Embodiments 9 and 10 of the present disclosure, it is possible to provide a display apparatus that satisfies reflective visibility in a desired area.

According to an example embodiment of the present disclosure, it is possible to provide various reflective visibility according to a ratio of the dye by adjusting the ratio of the dye included in the adhesive. For example, since the reflective visibility (a*) of Comparative Examples 1 and 2 is biased towards a greenish area, the ratio of the red dye is adjusted to adjust the reflective visibility (a*) to a reddish area. Accordingly, since the ratio of the dye included in the adhesive can be adjusted, it is possible to provide a display apparatus with improved reflective visibility in a desired area by providing the reflective visibility according to a ratio of the dye.

The average of reflective visibility (a*) of Example Embodiments 1 to 4 of the present disclosure can be substantially similar to the average of reflective visibility (a*) of Comparative Examples 1 and 2. In addition, since the ratio of the red dye among the dyes included in the adhesives of Example Embodiments 5 and 6 of the present disclosure was high among the dyes included in the adhesives of Example Embodiments 1 to 4 of the present disclosure, the average of reflective visibility (a*) of Example Embodiments 5 and 6 of the present disclosure was shifted toward (+). For example, the reflective visibility (a*) was shifted to the reddish area. In addition, since the ratio of the red dye among the dyes included in the adhesives of Example Embodiments 7 and 8 of the present disclosure was high among the dyes included in the adhesives of Example Embodiments 5 to 6, the average of reflective visibility (a*) of Example Embodiments 7 and 8 of the present disclosure was shifted toward (+). Since the dyes of Example Embodiments 9 and 10 of the present disclosure constituted only the red dye, the average of reflective visibility (a*) of Example Embodiments 9 and 10 of the present disclosure was shifted toward the most (+) side.

It was measured that the average of reflective visibility (b*) of Comparative Examples 1 and 2 was −3.62, the average of reflective visibility (b*) of Example Embodiments 1 and 2 of the present disclosure was −2.44, and the average of reflective visibility (b*) of Example Embodiments 3 and 4 of the present disclosure was −3.29. It was measured that the average of reflective visibility (b*) of Example Embodiments 5 and 6 of the present disclosure was −2.49, the average of reflective visibility (b*) of Example Embodiments 7 and 8 of the present disclosure was −2.82, and the average of reflective visibility (b*) of Example Embodiments 9 and 10 of the present disclosure was −2.20.

It can be seen that Example Embodiments 1 to 4 of the present disclosure have reflective visibility similar to Comparative Examples 1 and 2. Accordingly, it can be seen that Example Embodiments 1 to 4 of the present disclosure have an original color of the display panel.

According to an example embodiment of the present disclosure, since the ratio of the dyes included in the adhesive is adjusted, the color or reflective visibility of the adhesive can be adjusted. In addition, since the ratio of the dye included in the adhesive is adjusted, it is possible to reduce the reflectance by adjusting the transmittance of the adhesive, and to provide a display apparatus capable of adjusting the reflective visibility of a desired color.

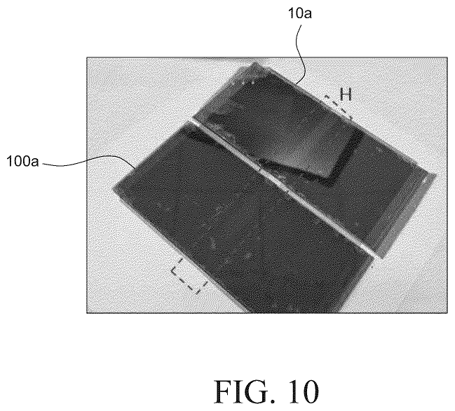

FIG. 10 illustrates reflective visibility according to Example Embodiments of the present disclosure and Comparative Examples.

In FIG. 10, the reflective visibility was measured after the display apparatus was turned off. In FIG. 10, in Comparative Example 10a, the first adhesive 701 to the sixth adhesive 905 of FIG. 4A or 4B are configured as transparent adhesives. In Example Embodiment 100a of the present disclosure, the first adhesive 701, the second adhesive 703, and the sixth adhesive 905 of FIG. 4A or 4B are configured as the adhesive including the color material and the UV blocker. The configuration of the adhesive of Example Embodiment 100a of the present disclosure does not limit one or more embodiments of the present disclosure.

Referring to FIG. 10, it can be seen that in Comparative Example 10a, a defect occurs in a hinge portion H, which is the lowest structure of the display apparatus. For example, an opening pattern in the hinge portion H, which is the lowest structure, can be transferred so that a defect can occur. The hinge portion H can be the first plate 610 described in FIG. 4A or 4B. When evaluated with the naked eye from the top of the display panel, a boundary between the hinge portion and an area without the hinge portion and/or a pattern within the hinge portion is transferred, so that the pattern of the hinge portion H can be recognized. For example, when the display apparatus is folded, defects caused by pattern transfer can occur due to pressing of the adhesive at the hinge portion H.

Referring to FIG. 10, in Example Embodiment 100a of the present disclosure, it is possible to minimize the defects caused by pattern transfer due to pressing of the adhesive at the hinge portion H when the display apparatus is folded, and to improve overall black visibility.

FIG. 11 illustrates surface treatment of an adhesive according to an example embodiment of the present disclosure.

Referring to FIG. 11, a surface-treatment apparatus S, and a mask or a film M can be included for surface-treatment of an adhesive.

The surface-treatment apparatus S can perform corona treatment or plasma treatment, and example embodiments of the present disclosure are not limited thereto. For example, the corona treatment can be formed at an air atmosphere (CDA), 0.7 kW (power), and a stage movement speed of 300 mm/sec, and example embodiments of the present disclosure are not limited thereto. For example, the plasma treatment can be formed at the air atmosphere (CDA) and the stage movement speed of 300 mm/sec, and example embodiments of the present disclosure are not limited thereto. For example, the strength and/or the stage movement speed can be adjusted during the corona treatment or plasma processing, and the surface treatment can be performed by distinguishing a location or an area where the surface-treatment is made according to the distribution of variable (or folding or bending) stress.

For example, the mask or film M can be metal or plastic, and example embodiments of the present disclosure are not limited thereto. For example, the mask or film M can be polyester terephthalate or polyester, and example embodiments of the present disclosure are not limited thereto. The mask or film M can be a patterned mask or film. The location of the pattern and the size of the pattern can vary depending on a curvature value or curvature type in the variable area of the display apparatus. Here, the first adhesive 701 is described as an example, and the same can also be applied to the second adhesive 703 to the sixth adhesive 905.

Referring to FIG. 11, the surface-treatment can be different according to the area of the first adhesive 701 constituted by the mask or film M on the first adhesive 701. The first adhesive 701 can be partially surface-treated by using the surface-treatment apparatus S through the mask or film M. A first portion a which does not correspond to the mask or film M can be surface-treated. A second portion b can correspond to the mask or film M, and the second portion b is hidden by the mask or film M, so the second portion b is not surface-treated. Thus, the first portion a can have a different surface from the second portion b. The surface-treated first portion a can become the first area 701a in FIGS. 4A and 4B. The second portion b can become the second area 701b in FIGS. 4A and 4B.

The surface-treated first portion a of the first adhesive 701 can have a different wettability from the second portion b. The wettability can be a phenomenon in which gas contacting a solid is replaced with a liquid. The wettability can be wetness, and is not limited to the terminology. A third portion c can be between the first portions a. For example, the third portion c can be the variable area. The surface of the first portion a adjacent to the variable area can be different from the surface of the second portion b. For example, the wettability of the first portion a adjacent to the variable area can be different from the wettability of the second portion b. Thus, the first portion a adjacent to the variable area can reduce or minimize waviness which occurs in the variable area. For example, the foldable display apparatus is a flat state in initial production, but after the variable area, e.g., the folding area, is folded and deformed, even though the variable area, e.g., the folding area, is unfolded again, the variable area, e.g., the folding area, need not be restored to the flat state upon initial production, e.g., 100%. This occurs due to the deformation of the adhesive and/or other components, and thus the waviness occurs in the folding area.

Referring to FIGS. 4A and 4B, the surface-treated first area 701a of the first adhesive 701 can have a different surface from the second area 701b. For example, the surface-treated first area 701a of the first adhesive 701 can have a different wettability from the second area 701b. The third portion c can be between the first portions 701a. For example, the third portion c can be the variable area VA. The surface of the first area 701a adjacent to the variable area VA can be different from the surface of the second area 701b. For example, the wettability of the first area 701a adjacent to the variable area VA can be different from the wettability of the second area 701b. Thus, the first area 701a adjacent to the variable area VA can reduce or minimize the waviness which occurs in the variable area VA.

The second adhesive 703 can include a first area 703a and a second area 703b. The second adhesive 703 can be surface-treated by the surface-treatment apparatus S. Thus, the surface-treated first area 703a of the second adhesive 703 can have a different surface from the second area 703b. For example, the surface-treated first area 703a of the second adhesive 703 can have a different wettability from the second area 703b. The surface of the first area 703a adjacent to the variable area VA can be different from the surface of the second area 703b. For example, the wettability of the first area 703a adjacent to the variable area VA can be different from the wettability of the second area 703b. Thus, the first area 703a adjacent to the variable area VA can reduce or minimize the waviness which occurs in the variable area VA.

The third adhesive 705 can include a first area 705a and a second area 705b. The third adhesive 705 can be surface-treated by the surface-treatment apparatus S. Thus, the surface-treated first area 705a of the third adhesive 705 can have a different surface from the second area 705b. For example, the surface-treated first area 705a of the third adhesive 705 can have a different wettability from the second area 705b. The surface of the first area 705a adjacent to the variable area VA can be different from the surface of the second area 705b. For example, the wettability of the first area 705a adjacent to the variable area VA can be different from the wettability of the second area 705b. Thus, the first area 705a adjacent to the variable area VA can reduce or minimize the waviness which occurs in the variable area VA.

The fourth adhesive 901 can include a first area 901a and a second area 901b. The fourth adhesive 901 can be surface-treated by the surface-treatment apparatus S. Thus, the surface-treated first area 901a of the fourth adhesive 901 can have a different surface from the second area 901b. For example, the surface-treated first area 901a of the fourth adhesive 901 can have a different wettability from the second area 901b. The surface of the first area 901a adjacent to the variable area VA can be different from the surface of the second area 901b. For example, the wettability of the first area 901a adjacent to the variable area VA can be different from the wettability of the second area 901b. Thus, the first area 901a adjacent to the variable area VA can reduce or minimize the waviness which occurs in the variable area VA.

The fifth adhesive 903 can include a first area 903a and a second area 903b. The fifth adhesive 903 can be surface-treated by the surface-treatment apparatus S. Thus, the surface-treated first area 903a of the fifth adhesive 903 can have a different surface from the second area 903b. For example, the surface-treated first area 903a of the fifth adhesive 903 can have a different wettability from the second area 903b. The surface of the first area 903a adjacent to the variable area VA can be different from the surface of the second area 903b. For example, the wettability of the first area 903a adjacent to the variable area VA can be different from the wettability of the second area 903b. Thus, the first area 903a adjacent to the variable area VA can reduce or minimize the waviness which occurs in the variable area VA.

The sixth adhesive 905 can include a first area 905a and a second area 905b. The sixth adhesive 905 can be surface-treated by the surface-treatment apparatus S. Thus, the surface-treated first area 905a of the sixth adhesive 905 can have a different surface from the second area 905b. For example, the surface-treated first area 905a of the sixth adhesive 905 can have a different wettability from the second area 905b. The surface of the first area 905a adjacent to the variable area VA can be different from the surface of the second area 905b. For example, the wettability of the first area 905a adjacent to the variable area VA can be different from the wettability of the second area 905b. Thus, the first area 905a adjacent to the variable area VA can reduce or minimize the waviness which occurs in the variable area VA.

According to an example embodiment of the present disclosure, since the adhesive is partially differently surface-treated, a display apparatus can be provided in which the curvature in the variable area can be reduced or minimized.

Referring to FIGS. 4A and 4B, the wettability can vary from the first adhesive 701 to the third adhesive 705. For example, the wettability can become smaller from the first adhesive 701 to the third adhesive 705. The transmittance of the adhesive can vary from the first adhesive 701 to the third adhesive 705. For example, the transmittance of the adhesive can become larger from the first adhesive 701 to the third adhesive 705. For example, the transmittance of the first adhesive 701 can be configured as 70%, the transmittance of the second adhesive 703 can be configured as 75%, and the transmittance of the third adhesive 705 can be configured as 80%, and the example embodiments of the present disclosure are not limited thereto. Thus, it is possible to reduce or minimize the waviness which occurs in the variable area VA. In addition, since the ultraviolet rays from the outside can be blocked or prevented or reduced, the performance and/or reliability of the display apparatus can be improved.

According to an example embodiment of the present disclosure, the surface-treated portions of the first adhesive 701, the second adhesive 703, and the third adhesive 705 can have a larger wettability than portions which are not surface-treated. Since the first adhesive 701, the second adhesive 703, and the third adhesive 705 are surface-treated, the wettabilities of the first adhesive 701, the second adhesive 703, and the third adhesive 705 can be similar. In addition, the transmittances of the first adhesive 701, the second adhesive 703, and the third adhesive 705 can be similar. Since the adhesive is configured by the adhesive which is partially surface-treated, the waviness which occurs in the variable area VA can be reduced or minimized. In addition, the transmittance of the adhesive is lowered to improve a defect or an external defect viewed by transferring the pattern on the plate.

Referring to FIGS. 4A and 4B, the surface-treated portions of the fourth adhesive 901, the fifth adhesive 903, and the sixth adhesive 905 can have a larger wettability than portions which are not surface-treated. Since the fourth adhesive 901, the fifth adhesive 903, and the sixth adhesive 905 are surface-treated, the wettabilities of the fourth adhesive 901, the fifth adhesive 903, and the sixth adhesive 905 can be similar. In addition, the transmittances of the fourth adhesive 901, the fifth adhesive 903, and the sixth adhesive 905 can be similar. Since the adhesive is configured by the adhesive which is surface-treated and has a low transmittance, the waviness which occurs in the variable area VA can be reduced or minimized. In addition, since the ultraviolet rays from the outside can be blocked or prevented or reduced, the performance and/or reliability of the display apparatus can be improved.

According to an embodiment of the present disclosure, the surface-treated portions of the fourth adhesive 901, the fifth adhesive 903, and the sixth adhesive 905 can have a larger wettability than portions which are not surface-treated. Since the fourth adhesive 901, the fifth adhesive 903, and the sixth adhesive 905 are surface-treated, the wettabilities of the fourth adhesive 901, the fifth adhesive 903, and the sixth adhesive 905 can be similar. In addition, the transmittances of the fourth adhesive 901, the fifth adhesive 903, and the sixth adhesive 905 can be similar. Since the adhesive is configured by the adhesive which is partially surface-treated, the waviness which occurs in the variable area VA can be reduced or minimized. In addition, by lowering the reflectance by lowering the transmittance, light resistance can be improved.

According to an example embodiment of the present disclosure, a plurality of first adhesives can be divided into or include a first group and a second group. For example, the first group of the plurality of first adhesives can be disposed between the one or more plates. For example, the first group of the plurality of first adhesives can include at least one of the first adhesive 701, the second adhesive 703, and the third adhesive 705. For example, the second group of the plurality of first adhesives can be disposed between the one or more cover members. For example, the second group of the plurality of first adhesives can include at least one of the fourth adhesive 901, the fifth adhesive 903, and the sixth adhesive 905. For example, the one or more second adhesives can include at least one of the seventh adhesive 801, the eighth adhesive 803, and the ninth adhesive 805 in or at the hole area HA. For example, a wettability of the one or more second adhesives can be different from a wettability of the one or more first adhesives.

According to an example embodiment of the present disclosure, the transmittances of the fourth adhesive 901, the fifth adhesive 903, and the sixth adhesive 905 can be higher than the transmittances of the first adhesive 701, the second adhesive 703, and the third adhesive 705. For example, since the fourth adhesive 901, the fifth adhesive 903, and the sixth adhesive 905 are configured at an upper portion of the display panel, the transmittances of the fourth adhesive 901, the fifth adhesive 903, and the sixth adhesive 905 can be configured to be higher than the transmittances of the first adhesive 701, the second adhesive 703, and the third adhesive 705. Thus, it is possible to provide a display apparatus that can minimize the deterioration of the luminance.

The shape of the surface of the first adhesive 701 can vary depending on the shape of the curvature. For example, the shape of the surface of the first adhesive 701 can vary from the first portion a to the second portion b. For example, the shape of the surface of the first adhesive 701 can vary from the second portion b to the first portion a. For example, the shape of the surface of at least one of the second adhesive 703 to the sixth adhesive 905 can vary from the first portion a to the second portion b. For example, the shape of the surface of at least one or more of the second adhesive 703 to the sixth adhesive 905 can vary from the second portion b to the first portion a.

Referring to both FIGS. 4A and 4B, the shape of the surface of the first adhesive 701 can vary from the first area 701a to the second area 701b. For example, the shape of the surface of at least one of the second adhesive 703 to the sixth adhesive 905 can also equally vary from the first area to the second area. For example, the shape of the surface of the first adhesive 701 can vary from the second area 701b to the first area 701a. For example, the shape of the surface of at least one of the second adhesive 703 to the sixth adhesive 905 can vary from the second area to the first area.

For example, the first portion a can be an area adjacent to at least one opening pattern 610h of the first plate 610. Since the shape of the surface of the first portion a can be different by the surface-treatment of the first adhesive 701, a curvature defect which occurs due to pressing of the first adhesive 701 in the area of at least one opening pattern 610h of the first plate 610 can be improved.

Since the surface-treatment of the first adhesive 701 is configured differently for each area or partially, the areas can have different adhesion forces, e.g., cohesion forces or surface coupling forces (or interface coupling forces). Thus, the curvature in the area which causes the waviness can be reduced or minimized.

According to an example embodiment of the present disclosure, the display area AA can include the variable area VA and the first area adjacent to the variable area VA. The surface of at least one adhesive in the first area 701a can be different from the surface of at least one adhesive in the variable area VA.

According to an example embodiment of the present disclosure, the surfaces of one or more adhesives 701, 703, and 705 in the first area adjacent to one or more opening patterns 610h can be different from the surfaces of one or more adhesives 701, 703, and 705 corresponding to one or more opening patterns 610h. According to an example embodiment of the present disclosure, the transmittances of one or more adhesives 701, 703, and 705 can be configured to be different as one or more adhesives 701, 703, and 705 move away from one or more plates 610, 620, and 630 including one or more opening patterns 610h.

Referring to FIGS. 4A and 4B, one or more adhesives 701, 703, and 705 between one or more plates 610, 620, and 630 can include first areas 701a, 703a, and 705a and second areas 701b, 703b, and 705b. The second areas 701b, 703b, and 705b can be adjacent to the first areas 701a, 703a, and 705a. The surfaces of the first areas 701a, 703a, and 705a can be different from the surfaces of the second areas 701b, 703b, and 705b.

Referring to FIGS. 4A and 4B, one or more adhesives 901, 903, and 905 between one or more cover members 710, 720, and 730 can vary from the color filter part 5000 to one or more cover members 710, 720, and 730. For example, with respect to one or more adhesives 901, 903, and 905 between one or more cover members 710, 720, and 730, the transmittances of one or more adhesives 901, 903, and 905 can be configured differently from the color filter part 500 to one or more cover members 710, 720, and 730.

For example, with respect to one or more adhesives 901, 903, and 905 between one or more cover members 710, 720, and 730, the surface-treatments of one or more adhesives 901, 903, and 905 can be configured differently from the color filter part 5000 to one or more cover members 710, 720, and 730. For example, one or more adhesives 901, 903, and 905 between one or more cover members 710, 720, and 730 can include first areas 901a, 903a, and 905a and second areas 901b, 903b, and 905b. The second areas 901b, 903b, and 905b can be adjacent to the first areas 901a, 903a, and 905a. The surfaces of the first areas 901a, 903a, and 905a can be different from the surfaces of the second areas 901b, 903b, and 905b.

In Table 2 below, adhesion forces (unit: kgf/inch (kilogram force/inch) after the surface-treatment according to Example Embodiments of the present disclosure and the Comparative Examples are measured. The adhesion force can be an interface adhesion force between the adhesive and the glass. The adhesive is formed on the glass, and then surface-treated to measure the adhesion force. For example, the glass can be the second cover member 720.

TABLE 2

| | | Example | Example | Example | Example | Example |
|---|---|---|---|---|---|---|
| | Comparative | Embodiment | Embodiment | Embodiment | Embodiment | Embodiment |
| | Example | 11 | 12 | 13 | 14 | 15 |
| Room | 0.90 | 1.70 | 1.79 | 1.19 | 1.75 | 1.43 |
| temp. | | | | | | |
| 60° C., | 0.77 | 1.50 | 1.44 | 0.80 | 1.35 | 1.19 |
| 90% | | | | | | |
| 80° C. | 0.76 | 1.04 | — | — | — | 1.03 |
| 85° C., | 0.67 | 1.31 | — | — | — | 1.14 |
| 85% | | | | | | |

In Table 2, 60° C. indicates a temperature and 90% indicates a humidity. Under temperature and humidity conditions, after 240 hours, the adhesion force is measured. The adhesion forces at 80° C. and 85° C. in Example Embodiments 12 to 14 are not measured, but can be similar to the adhesion forces in Example Embodiments 11 and 15.

Referring to Table 2, in the Comparative Examples, the fifth adhesive 903 is not surface-treated. In Example Embodiments 11 to 15, the first area 903a of the fifth adhesive 903 is surface-treated in FIG. 11. The fifth adhesive is an adhesive having a transmittance of 75 to 80%, and the content are not limited to the content of the present disclosure. In the Example Embodiment 11, both surfaces of the adhesive is corona-treated. In the Example Embodiment 12, a single surface of the adhesive is corona-treated. In the Example Embodiment 13, a single surface of the glass is corona-treated. In Example Embodiment 14, only ½ of the single surface of the adhesive is corona-treated. In the Example Embodiment 15, both surfaces of the adhesive is plasma-treated.

The surface-treatment can make the wettability of the adhesive different. For example, the wettability can indicate affinity or attachment easiness of the liquid to a solid surface. For example, good wettability can mean that the adhesion force increases.

Referring to Table 2, it can be seen that when the single surface and/or both surfaces of the adhesive are surface-treated, the adhesion force is enhanced as compared with the Comparative Examples of which surface is not treated. For example, it can be seen that when the adhesive is surface-treated as in Example Embodiments 11 to 15, the interface adhesion force between the glass and the adhesive has 1.43 kgf/inch to 1.79 kgf/inch at the room temperature, so the adhesion force is enhanced as compared with the comparative example in which the adhesive is not surface-treated.

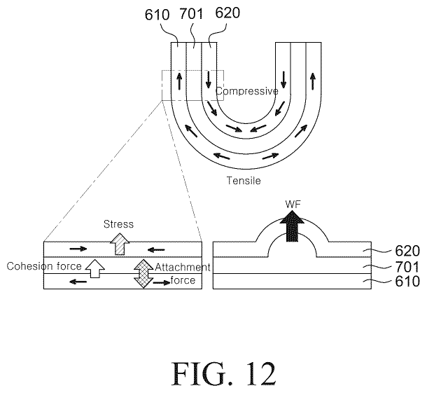

FIG. 12 is a diagram for describing curvature improvement of an adhesive according to an example embodiment of the present disclosure.

In FIG. 12, the first adhesive 701 is described as an example, and the same can also be applied to the second adhesive 703 to the sixth adhesive 905.

Referring to FIG. 12, the adhesion force of the first adhesive 701 can be generated as a sum of the cohesion force and the adhesion force generated at an interface. The cohesion force can be a mutual attraction between similar molecules in which the same molecules are attached to each other. For example, the cohesion force can be an intermolecular force which can be generated between molecules of the same material. Atoms or particles of the solid and the liquid can be attracted by the cohesion force. The adhesion force can be a mutual attraction between different molecules in which different molecules are attached to each other. For example, by the adhesion force, adhesion can occur between two different materials. The adhesion force can include an electrostatic force between two different molecules.

Upon folding, the first plate 610 on the bottom surface of the first adhesive 701 can be tensile, and the second plate 620 on the top surface of the first adhesive 701 can be compressive. When the first adhesive 701 is stressed, the curvature can occur in a direction in which the first adhesive 701 is stressed. An area of a force WF in which the curvature occurs is surface-treated, so the adhesion force in this area can be increased. The surface-treatment can make the wettability in a part where the curvature occurs different, so the surface-treatment can minimize the occurrence of the curvature. For example, it is possible to reduce or minimize the occurrence of the curvature in the area of the opening pattern of the plate.

A display apparatus according to one or more example embodiments of the present disclosure can be applied to or included in mobile devices, video telephones, smart watches, watch phones, wearable apparatuses, foldable apparatuses, rollable apparatuses, bendable apparatuses, flexible apparatuses, curved apparatuses, sliding apparatuses, variable apparatuses, electronic notebooks, electronic books, portable multimedia players (PMPs), personal digital assistants (PDAs), MP3 players, mobile medical apparatuses, desktop PCs, laptop PCs, netbook computers, workstations, navigation devices, vehicular navigation devices, vehicular display apparatuses, vehicular apparatuses, theater apparatuses, theater display apparatuses, televisions, a wallpaper apparatuses, signage apparatuses, game apparatuses, laptop computers, monitors, cameras, camcorders, and home appliance apparatuses. In addition, the display apparatus of the present disclosure can be applied to or included in an organic light emitting lighting apparatus or an inorganic light emitting lighting apparatus.

A display apparatus according to one or more embodiments of the present disclosure are described below.

A display apparatus according to one or more embodiments of the present disclosure can comprise one or more plates including a display area and a hole area, a transistor part over the one or more plates, a light emitting part over the transistor part, one or more cover members over the light emitting part, one or more first adhesives disposed between the one or more cover members and in the display area and one or more second adhesives disposed at the hole area, the one or more second adhesives being different from the one or more first adhesives.

According to one or more embodiments of the present disclosure, a transmittance of the one or more first adhesives can be different from a transmittance of the one or more second adhesives.

According to one or more embodiments of the present disclosure, a transmittance of the one or more first adhesives can be 80% or less.

According to one or more embodiments of the present disclosure, the transmittance of the one or more first adhesives can be about 70% or more to about 80% or less.

According to one or more embodiments of the present disclosure, the display area can include a variable area and a first area adjacent to the variable area, and a wettability of the one or more first adhesives in the first area can be different from a wettability of the one or more first adhesives in the variable area.

According to one or more embodiments of the present disclosure, at least one or more of a camera, a sensor, and an optical part can be disposed in the hole area.

According to one or more embodiments of the present disclosure, the display apparatus can further include an encapsulation part over the light emitting part and a color filter part over the encapsulation part.

According to one or more embodiments of the present disclosure, the display apparatus can further include a touch part between the encapsulation part and the color filter part.

According to one or more embodiments of the present disclosure, the display apparatus can further include one or more plates below the transistor part and one or more third adhesives between the one or more plates.

According to one or more embodiments of the present disclosure, at least one of the one or more plates can further include one or more opening patterns.

According to one or more embodiments of the present disclosure, the display apparatus can further include a first area adjacent to the one or more opening patterns. A wettability of the one or more third adhesives in the first area can be different from a wettability of the one or more third adhesives corresponding to the one or more opening patterns.

According to some embodiments of the present disclosure, the hole area can be disposed at a part of the one or more plates and a part of the one or more cover members.

According to one or more embodiments of the present disclosure, the hole area can extend from a part of the one or more plates to a part of the one or more cover members.

According to one or more embodiments of the present disclosure, at least one or more of the one or more first adhesives and the one or more third adhesives can include a color material and an ultraviolet ray blocker.

According to one or more embodiments of the present disclosure, the transmittance of the first adhesive can be higher than the transmittance of the third adhesive.

According to one or more embodiments of the present disclosure, the first adhesive can include two or more first adhesives, and the transmittance of the first adhesives can be similar. The third adhesive can include two or more third adhesives, and the transmittance of the third adhesives can be similar.

A display apparatus according to another embodiment of the present disclosure can comprise a transistor part over a substrate, a light emitting part over the transistor part, one or more cover members over the light emitting part and one or more first adhesives disposed between the one or more cover members, a transmittance of the one or more first adhesives can be 80% or less.

According to one or more embodiments of the present disclosure, the transmittance of the one or more first adhesives can be about 70% or more to about 80% or less.

According to one or more embodiments of the present disclosure, the display apparatus can further include an encapsulation part over the light emitting part and a color filter part over the encapsulation part.

According to one or more embodiments of the present disclosure, a transmittance of the one or more first adhesives can be differently configured in going away from the color filter part to the one or more cover members.

According to one or more embodiments of the present disclosure, the display apparatus can further include a touch part between the encapsulation part and the color filter part.

According to one or more embodiments of the present disclosure, the one or more first adhesives can include a first area and a second area adjacent to the first area, and a wettability of the first area can be different from a wettability of the second area.

According to one or more embodiments of the present disclosure, the display apparatus can further include a hole area on the periphery of the substrate, the hole area can include one or more second adhesives.

According to one or more embodiments of the present disclosure, the one or more second adhesives can be different from the one or more first adhesives.

According to one or more embodiments of the present disclosure, the one or more second adhesives can include transparent adhesives.

According to one or more embodiments of the present disclosure, at least one or more of a camera, a sensor, and an optical part can be disposed in the hole area.

According to one or more embodiments of the present disclosure, the display apparatus can further include one or more plates below the transistor part and one or more third adhesives between the one or more plates.

According to one or more embodiments of the present disclosure, at least one among the one or more plates can further include one or more opening patterns.

According to one or more embodiments of the present disclosure, the one or more third adhesives can include a first area adjacent to the one or more opening patterns, and a wettability of the one or more third adhesives in the first area can be different from a wettability of the one or more third adhesives corresponding to the one or more opening patterns.

According to one or more embodiments of the present disclosure, the one or more third adhesives can include a first area and a second area adjacent to the first area, and a wettability of the first area can be different from a wettability of the second area.

According to one or more embodiments of the present disclosure, the hole area can be disposed at a part of the one or more plates and a part of the one or more cover members.

According to one or more embodiments of the present disclosure, the hole area can extend from a part of the one or more plates to a part of the one or more cover members.

According to one or more embodiments of the present disclosure, at least one of the one or more first adhesives and the one or more third adhesives can include a color material and an ultraviolet ray blocker.

According to one or more embodiments of the present disclosure, a transmittance of the one or more third adhesives can be differently configured in going away from the one or more plates including the one or more opening patterns.

According to one or more embodiments of the present disclosure, the transmittance of the first adhesive can be higher than the transmittance of the third adhesive.

According to one or more embodiments of the present disclosure, the first adhesive can include two or more first adhesives, and the transmittance of the first adhesives can be similar. The third adhesive can include two or more third adhesives, and the transmittance of the third adhesives can be similar.

A display apparatus according to another embodiment of the present disclosure can comprise a transistor part over a substrate, a light emitting part over the transistor part, one or more cover members over the light emitting part, and one or more first adhesives disposed between the one or more cover members. A transmittance of the one or more first adhesives can be less than about 97%.

According to one or more embodiments of the present disclosure, the display apparatus can further include one or more plates including a display area and a hole area disposed on or at a periphery of the display area and one or more second adhesives disposed at the hole area. The one or more first adhesives can be disposed between the one or more cover members in the display area. The one or more second adhesives can have different transmittance from those of the one or more first adhesives.

According to one or more embodiments of the present disclosure, the transmittance of the one or more first adhesives can be about 70% or more to about 80% or less.

According to one or more embodiments of the present disclosure, the display area can include a variable area and a first area adjacent to the variable area. A wettability of the one or more first adhesives in the first area can be different from a wettability of the one or more first adhesives in the variable area.

According to one or more embodiments of the present disclosure, at least one or more of a camera, a sensor, and an optical part can be disposed in the hole area.

According to one or more embodiments of the present disclosure, the display apparatus can further include an encapsulation part over the light emitting part and a color filter part over the encapsulation part.

According to one or more embodiments of the present disclosure, the display apparatus can further include a touch part between the encapsulation part and the color filter part.

According to one or more embodiments of the present disclosure, the display apparatus can further include one or more third adhesives between the one or more plates. The one or more plates can be below the transistor part.

According to one or more embodiments of the present disclosure, at least one of the one or more plates can further include one or more opening patterns.

According to one or more embodiments of the present disclosure, the display apparatus can further include a first area adjacent to the one or more opening patterns. A wettability of the one or more third adhesives in the first area can be different from a wettability of the one or more third adhesives corresponding to the one or more opening patterns.

According to one or more embodiments of the present disclosure, the hole area can be disposed at a part of the one or more plates and a part of the one or more cover members.

According to one or more embodiments of the present disclosure, the hole area can extend from a part of the one or more plates to a part of the one or more cover members.

According to one or more embodiments of the present disclosure, at least one of the one or more first adhesives and the one or more third adhesives can include a color material and an ultraviolet ray blocker.

According to one or more embodiments of the present disclosure, the transmittance of the one or more first adhesives can be about 70% or more to about 80% or less.

According to one or more embodiments of the present disclosure, the transmittance of the one or more first adhesives can be differently configured in going away from the color filter part to the one or more cover members.

According to one or more embodiments of the present disclosure, the one or more second adhesives can include transparent adhesives.

According to one or more embodiments of the present disclosure, the one or more third adhesives can include a first area and a second area adjacent to the first area. A wettability of the first area can be different from a wettability of the second area.

According to one or more embodiments of the present disclosure, a transmittance of the one or more third adhesives can be differently configured in going away from the one or more plates including the one or more opening patterns.

A display apparatus according to another embodiment of the present disclosure can comprise one or more plates including a display area and a non-display area, a transistor part over the one or more plates, a light emitting part over the transistor part, one or more cover members over the light emitting part, and a plurality of first adhesives divided into a first group and a second group. The first group of the plurality of first adhesives can have a first transmittance and is disposed between the one or more plates. The second group of the plurality of first adhesives can have a second transmittance different from the first transmittance, and is disposed between the one or more cover members.

According to one or more embodiments of the present disclosure, the display apparatus can further include one or more second adhesives disposed at a hole area disposed on or at a periphery of the display area, the one or more second adhesives having a third transmittance. The third transmittance of the one or more second adhesives can be different from that of the one or more first adhesives.

A display apparatus according to another embodiment of the present disclosure can comprise two or more plates including a display area and a hole area disposed on or at a periphery of the display area, a transistor part over the plates, a light emitting part over the transistor part, a first adhesive disposed between the plates and in the display area, and a second adhesive disposed at the hole area. A transmittance of the first adhesive can be 80% or less.

According to one or more embodiments of the present disclosure, the display apparatus can further include two or more cover members over the light emitting part and a third adhesive disposed between the cover members and in the display area, the second adhesive being different from the one or more third adhesives.

According to one or more embodiments of the present disclosure, the transmittance of the third adhesive can be higher than the transmittance of the first adhesive.

It will be apparent to those skilled in the art that various modifications and variations can be made in the display apparatus of the present disclosure without departing from the scope of the disclosures. Thus, it is intended that the present disclosure covers the modifications and variations of this disclosure provided they come within the scope of the appended claims and their equivalents.

What is claimed is:

1. A display apparatus, comprising:
a transistor part over a substrate;
a light emitting part over the transistor part;
one or more cover members over the light emitting part; and
one or more first adhesives disposed between the one or more cover members,
wherein a transmittance of the one or more first adhesives is less than about 97%.

2. The display apparatus of claim 1, further comprising:
one or more plates including a display area and a hole area disposed on or at a periphery of the display area; and
one or more second adhesives disposed at the hole area,
wherein the one or more first adhesives are disposed between the one or more cover members in the display area, and
wherein the one or more second adhesives have different transmittance from those of the one or more first adhesives.

3. The display apparatus of claim 2, wherein the transmittance of the one or more first adhesives is about 70% or more to about 80% or less.

4. The display apparatus of claim 2, wherein the display area includes a variable area and a first area adjacent to the variable area, and
wherein a wettability of the one or more first adhesives in the first area is different from a wettability of the one or more first adhesives in the variable area.

5. The display apparatus of claim 2, wherein at least one or more of a camera, a sensor, and an optical part are disposed in the hole area.

6. The display apparatus of claim 2, further comprising:
an encapsulation part over the light emitting part; and
a color filter part over the encapsulation part.

7. The display apparatus of claim 6, further comprising:
a touch part between the encapsulation part and the color filter part.

8. The display apparatus of claim 2, further comprising:
one or more third adhesives between the one or more plates,
wherein the one or more plates are below the transistor part.

9. The display apparatus of claim 8, wherein at least one of the one or more plates further includes one or more opening patterns.

10. The display apparatus of claim 9, further comprising:
a first area adjacent to the one or more opening patterns,
wherein a wettability of the one or more third adhesives in the first area is different from a wettability of the one or more third adhesives corresponding to the one or more opening patterns.

11. The display apparatus of claim 8, wherein the hole area is disposed at a part of the one or more plates and a part of the one or more cover members.

12. The display apparatus of claim 8, wherein the hole area extends from a part of the one or more plates to a part of the one or more cover members.

13. The display apparatus of claim 8, wherein at least one of the one or more first adhesives and the one or more third adhesives include a color material and an ultraviolet ray blocker.

14. The display apparatus of claim 1, wherein the transmittance of the one or more first adhesives is about 70% or more to about 80% or less.

15. The display apparatus of claim 6, wherein the transmittance of the one or more first adhesives is differently configured in going away from the color filter part to the one or more cover members.

16. The display apparatus of claim 2, wherein the one or more second adhesives include transparent adhesives.

17. The display apparatus of claim 10, wherein the one or more third adhesives include a first area and a second area adjacent to the first area, and
wherein a wettability of the first area is different from a wettability of the second area.

18. The display apparatus of claim 17, wherein a transmittance of the one or more third adhesives is differently configured in going away from the one or more plates including the one or more opening patterns.

19. A display apparatus, comprising:
one or more plates including a display area and a non-display area;
a transistor part over the one or more plates;
a light emitting part over the transistor part;
one or more cover members over the light emitting part; and
a plurality of first adhesives divided into a first group and a second group,
wherein the first group of the plurality of first adhesives has a first transmittance and is disposed between the one or more plates, and
wherein the second group of the plurality of first adhesives has a second transmittance different from the first transmittance, and is disposed between the one or more cover members.

20. The display apparatus of claim 19, further comprising one or more second adhesives disposed at a hole area disposed on or at a periphery of the display area, the one or more second adhesives having a third transmittance,
wherein the third transmittance of the one or more second adhesives is different from that of the one or more first adhesives.
